(19) United States
(12) Patent Application Publication
(10) Pub. No.: US 2024/0120323 A1
(43) Pub. Date: Apr. 11, 2024

(54) DISPLAY DEVICE APPARATUS FOR FABRICATING DISPLAY PANEL AND FABRICATING METHOD THEREOF

(71) Applicant: Samsung Display Co., LTD., Yongin-si (KR)

(72) Inventors: Tae Hee LEE, Yongin-si (KR); Sung Kook PARK, Yongin-si (KR); Kyung Ho KIM, Yongin-si (KR); Young Seok SEO, Yongin-si (KR); Jae Gwang UM, Yongin-si (KR); Sang Hyun LEE, Yongin-si (KR); Hyung Suk HWANG, Yongin-si (KR)

(21) Appl. No.: 18/461,972

(22) Filed: Sep. 6, 2023

(30) Foreign Application Priority Data
Oct. 6, 2022 (KR) 10-2022-0127956
Nov. 23, 2022 (KR) 10-2022-0157875

(51) Int. Cl. H01L 25/075

(52) U.S. Cl. CPC H01L 25/0753

(57) ABSTRACT

The present disclosure relates to an apparatus for fabricating a display panel including: an attachment member having a fixing portion in a pressurization direction to which a pressurization header is fixed, an attachment driving member configured to move the attachment member and the pressurization header in the pressurization direction or a detachment direction through a fixing frame of the attachment member, a first pressure sensing module between the pressurization header and the attachment member and configured to generate first pressure detection signals according to pressure applied to the pressurization header, a gradient setting module configured to set a gradient of the pressurization header based on magnitudes of the first pressure detection signals, and a gradient control module configured to adjust gradients of the pressurization header, the attachment member, and the fixing frame according to control of the gradient setting module.

### CROSS-REFERENCE TO RELATED APPLICATION

This application claims priority to and the benefit of Korean Patent Application No. 10-2022-0127956, filed on Oct. 6, 2022, and Korean Patent Application No. 10-2022-0157875, filed on Nov. 23, 2022, in the Korean Intellectual Property Office, the entire content of which is incorporated by reference herein.

### BACKGROUND

### 1. Field

The present disclosure relates to an apparatus for fabricating a display panel and a fabricating method thereof.

### 2. Description of the Related Art

The importance of display devices has increased with the development of multimedia. Accordingly, various types of display devices such as organic light emitting diode (OLED) displays and liquid crystal displays (LCDs) have been used.

The display devices are devices for displaying images, and include display panels such as light emitting display panels or liquid crystal display panels. Among them, the light emitting display panel may include light emitting diodes (LEDs), and such light emitting diodes include organic light emitting diodes (OLEDs) that use an organic material as a fluorescent material, inorganic light emitting diodes that use an inorganic material as a fluorescent material, or the like.

When a display panel that uses inorganic light emitting diodes as light emitting elements is fabricated, fabricating apparatuses for precisely disposing and attaching light emitting diodes such as micro LEDs onto a substrate of the display panel are required.

### SUMMARY

Aspects and features of embodiments of the present disclosure provide an apparatus for fabricating a display panel and a fabricating method thereof capable of precisely and accurately disposing and attaching light emitting diodes.

Aspects and features of embodiments of the present disclosure also provide an apparatus for fabricating a display panel and a fabricating method thereof capable of reducing or minimizing an attachment defective rate of light emitting diodes by allowing a gradient of a pressurization member pressurizing and attaching the light emitting diodes to be easily corrected.

However, aspects and features of embodiments of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, an apparatus for fabricating a display panel, including an attachment member having a fixing portion in a pressurization direction to which a pressurization header is fixed, an attachment driving member configured to move the attachment member and the pressurization header in the pressurization direction or a detachment direction through a fixing frame of the attachment member, a first pressure sensing module between the pressurization header and the attachment member and configured to generate first pressure detection signals according to pressure applied to the pressurization header, a gradient setting module configured to set a gradient of the pressurization header based on magnitudes of the first pressure detection signals, and a gradient control module configured to adjust gradients of the pressurization header, the attachment member, and the fixing frame according to control of the gradient setting module.

In one or more embodiments, the attachment member has a polyprismatic shape or a cylindrical shape and has a polygonal shape or a circular shape opening, wherein an insertion hole into which the pressurization header is inserted and fixed is located in a fixing part of the attachment member in the pressurization direction, and wherein the insertion hole has a polygonal or cylindrical shape according to a shape of an outer peripheral surface of the pressurization header.

In one or more embodiments, an inner step is located in the fixing part according to a difference in inner diameter between the opening of the attachment member and the insertion hole, and the first pressure sensing module is on the inner step of the fixing part.

In one or more embodiments, the first pressure sensing module has a quadrangular ring or O-ring shape corresponding to a shape and an area of the inner step of the fixing part or is separated into a plurality of pieces and the plurality of pieces of the first pressure sensing module are separately located on the inner step of the fixing part, and the pressurization header is inserted into the insertion hole of the fixing part and contacting the first pressure sensing module.

In one or more embodiments, the pressurization header includes a transparent material including at least one of light-transmitting quartz or glass, and has a hexahedral shape, a cube shape, a cylindrical shape, or a column shape corresponding to a shape and a size of the insertion hole in the fixing part of the attachment member.

In one or more embodiments, the first pressure sensing module is configured to sense a magnitude of the pressure applied to the pressurization header using a plurality of pressure sensors located, respectively, at positions in different directions and generates the first pressure detection signals based on the magnitude of the pressure, and transmit the first pressure detection signals together with a directional code for each of the plurality of pressure sensors to the gradient setting module using at least one signal transmission circuit.

In one or more embodiments, the plurality of pressure sensors are: located, respectively, in x-axis, −x-axis, y-axis, and −y-axis directions on the inner step of the fixing part, located, respectively, at four-direction corner positions of the inner step formed in a quadrangular shape, or located on the inner step and have one polygonal shape selected from the group of a triangular shape, a quadrangular shape, a pentagonal shape, or a hexagonal shape on the inner step.

In one or more embodiments, the gradient setting module is configured to: detect a magnitude deviation between the first pressure detection signals and calculate horizontal gradient setting values of the pressurization header to make the magnitude deviation between the first pressure detection signals zero, and generate gradient control signals corresponding to magnitudes of the calculated horizontal gradient setting values and transmits the gradient control signals to the gradient control module.

In one or more embodiments, the attachment driving member is configured to move the fixing frame, the attachment member, and the pressurization header in the pressurization direction or the detachment direction opposite to the pressurization direction using a plurality of pressure regulators located in a downward direction of a flat plate support frame.

In one or more embodiments, the gradient control module includes a plurality of linear motion (LM) guides, the plurality of LM guides located at positions corresponding to the plurality of pressure regulators on a rear surface portion of the flat plate support frame, a plurality of magnet springs supporting the plurality of LM guides, respectively, and at least one servo motor configured to adjust horizontal gradients of the flat plate support frame and the plurality of pressure regulators by changing a disposition position of each of the plurality of magnet springs and the plurality of LM guides according to the gradient control signals from the gradient setting module.

In one or more embodiments, the gradient control module is configured to adjust horizontal gradients of the plurality of pressure regulators, the attachment member, and the pressurization header located on the flat plate support frame by adjusting the horizontal gradient of the flat plate support frame of the attachment driving member based on the gradient control signals.

In one or more embodiments, a second pressure sensing module located in a pressurization holder of a pressurization plate pressurized by the pressurization header and generating second pressure detection signals according to a magnitude of pressure applied from the pressurization header, wherein the second pressure sensing module is in a flat plate shape corresponding to a shape and an area of the pressurization holder or is separately located inside the pressurization holder in the form of pieces.

In one or more embodiments, the second pressure sensing module is configured to generate the second pressure detection signals according to the magnitude of the pressure applied from the pressurization header using a plurality of pressure sensors located, at positions in different directions, and transmit the second pressure detection signals together with a directional code for each of the plurality of pressure sensors to the gradient setting module through at least one signal transmission circuit.

In one or more embodiments, the gradient setting module is configured to detect a magnitude deviation between the second pressure detection signals and to calculate horizontal gradient setting values of the pressurization header to make the magnitude deviation between the second pressure detection signals zero.

In one or more embodiments, the plurality of pressure sensors: are located, respectively, in x-axis, −x-axis, y-axis, and −y-axis directions inside the pressurization holder of the pressurization plate, are located, respectively, at four-direction corner positions inside the pressurization holder formed in a quadrangular shape, or has one polygonal shape of a triangular shape, a quadrangular shape, a pentagonal shape, or a hexagonal shape inside the pressurization holder.

In one or more embodiments, the gradient setting module is configured to detect pressure magnitude deviations according to the second pressure detection signals, to calculate horizontal gradient setting values to adjust a horizontal gradient of the pressurization header to make the pressure magnitude deviation according to the second pressure detection signals zero, to generate gradient control signals corresponding to magnitudes of the calculated horizontal gradient setting values, and to transmit the gradient control signals to the gradient control module.

In one or more embodiments, the gradient control module is configured to adjust horizontal gradients of the plurality of pressure regulators, the attachment member, and the pressurization header located on the flat plate support frame by adjusting a horizontal gradient of a flat plate support frame of the attachment driving member based on the gradient control signals.

According to one or more embodiments of the present disclosure, a fabricating method of a display panel, including fixing a pressurization header to a fixing part, in a pressurization direction, of an attachment member, moving a fixing frame of the attachment member, the attachment member, and the pressurization header in the pressurization direction using an attachment driving member, generating first pressure detection signals according to pressure applied to the pressurization header using a first pressure sensing module, and setting a gradient of the pressurization header based on magnitudes of the first pressure detection signals and adjusting gradients of the pressurization header, the attachment member, and the fixing frame.

In one or more embodiments, the generating of the first pressure detection signals includes sensing a magnitude of the pressure applied to the pressurization header using a plurality of pressure sensors located, respectively, between the pressurization header and the fixing part and generating the first pressure detection signals based on the magnitude of the pressure, and transmitting the first pressure detection signals together with a directional code for each of the plurality of pressure sensors to a gradient setting module using at least one signal transmission circuit. In one or more embodiments, the adjusting of the gradients of the pressurization header, the attachment member, and the fixing frame includes detecting a magnitude deviation between the first pressure detection signals and calculating horizontal gradient setting values of the pressurization header for making the magnitude deviation between the first pressure detection signals zero, and generating gradient control signals corresponding to magnitudes of the calculated horizontal gradient setting values and adjusting the gradients of the pressurization header, the attachment member, and the fixing frame according to the gradient control signals. With an apparatus for fabricating a display panel according to embodiments, it is possible to improve fabrication efficiency and reliability of the display panel by precisely and accurately disposing and attaching light emitting diodes onto a display substrate.

In addition, it is possible to reduce or minimize an attachment defective rate of light emitting diodes and reduce a fabrication cost by allowing a gradient of a pressurization member pressurizing and attaching the light emitting diodes to be easily corrected.

The effects, aspects, and features of embodiments of the present disclosure are not limited to the aforementioned effects, aspects, and features, and various other effects, aspects, and features are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to one or more embodiments of the present disclosure;

FIG. 2 is a schematic plan view illustrating emission areas of respective pixels according to one or more embodiments;

FIG. 3 is a schematic plan view illustrating emission areas of respective pixels according to one or more embodiments;

FIG. 4 is an equivalent circuit diagram of each pixel according to one or more embodiments;

FIG. 5 is an equivalent circuit diagram of each pixel according to one or more embodiments;

FIG. 6 is a schematic cross-sectional view according to one or more embodiments taken along the line A-A′ of FIG. 2;

FIG. 7 is a schematic enlarged view illustrating a first emission area of FIG. 6,

FIG. 8 is a cross-sectional view illustrating a light emitting element of FIG. 7 in detail;

FIG. 9 is a schematic cross-sectional view according to one or more embodiments taken along the line A-A′ of FIG. 2;

FIG. 10 is a schematic cross-sectional view according to one or more embodiments taken along the line A-A′ of FIG. 2;

FIG. 11 is a schematic perspective view illustrating an apparatus for fabricating a display panel according to one or more embodiments;

FIG. 12 is a cross-sectional view illustrating a cross-sectional structure of the apparatus for fabricating a display panel illustrated in FIG. 11;

FIG. 13 is a cross-sectional view illustrating cross-sectional structures of an attachment member and a fixing part of the attachment member illustrated in FIG. 12;

FIG. 14 is a configuration view illustrating lower surfaces of a pressurization header, the attachment member, and a fixing frame of FIGS. 12 and 13 in an upward direction;

FIG. 15 is a configuration view of one or more embodiments illustrating lower surfaces of a pressurization header, the attachment member, and the fixing frame of FIGS. 12 and 13 in an upward direction;

FIG. 16 is a configuration view of one or more embodiments illustrating a disposition shape of a first pressure sensing module illustrated in FIGS. 14 and 15;

FIG. 17 is a configuration view of one or more embodiments illustrating a disposition shape of a first pressure sensing module illustrated in FIGS. 14 and 15;

FIG. 18 is a configuration view illustrating a structure, in a plan view, of a gradient control module illustrated in FIGS. 11 and 12;

FIG. 19 is a cross-sectional structural view for describing a pressurizing process of a second pressure sensing module through the pressurization header, and a horizontal gradient correcting process of the pressurization header;

FIG. 20 is a cross-sectional view illustrating, in detail, cross-sectional structures of a pressurization plate, and the second pressure sensing module illustrated in FIG. 19;

FIG. 21 is a front view illustrating a disposition structure of the pressurization plate and the second pressure sensing module illustrated in FIGS. 19 and 20;

FIG. 22 is a front view of one or more embodiments illustrating a disposition structure of the pressurization plate and the second pressure sensing module illustrated in FIGS. 19 and 20;

FIG. 23 is a cross-sectional structural view illustrating a fabricating process of a display panel using the apparatus for fabricating a display panel according to one or more embodiments;

FIG. 24 is a perspective view illustrating, in detail, a wafer mounting member illustrated in FIG. 23;

FIG. 25 is a cross-sectional structural view illustrating a wafer pressurizing process using the apparatus for fabricating a display panel according to one or more embodiments;

FIG. 26 is an illustrative view illustrating an instrument board and a center fascia of a vehicle including the display device according to one or more embodiments;

FIG. 27 is an illustrative view illustrating a glasses-type virtual reality device including the display device according to one or more embodiments;

FIG. 28 is an illustrative view illustrating a watch-type smart device including the display device according to one or more embodiments; and

FIG. 29 is an illustrative view illustrating a transparent display device including the display device according to one or more embodiments.

### DETAILED DESCRIPTION

One or more embodiments of the present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings and scope of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, specific embodiments will be described with reference to the accompanying drawings.

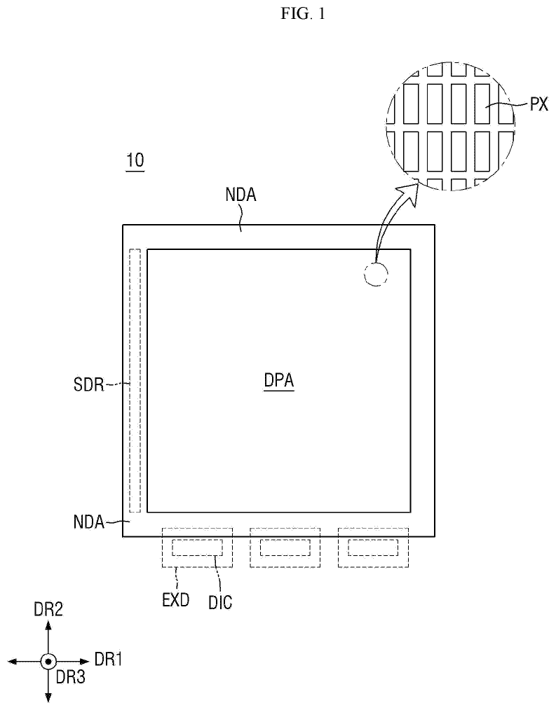

FIG. 1 is a plan view of a display device according to one or more embodiments of the present disclosure.

Referring to FIG. 1, a display device 10 according to one or more embodiments may be applied to smartphones, mobile phones, tablet personal computers (PCs), personal digital assistants (PDAs), portable multimedia players (PMPs), televisions, game machines, wrist watch-type electronic devices, head-mounted displays, monitors of personal computers, laptop computers, vehicle navigation systems, vehicle instrument boards, digital cameras, camcorders, external billboards, electric signs, medical devices, inspection devices, various home appliances such as refrigerators and washing machines, and/or Internet of Things (IoT) devices. In the present disclosure, a television (TV) will be described as an example of the display device, and the TV may have high resolution or ultra-high resolution such as high definition (HD), ultra-high definition (UHD), 4K, or 8K.

In addition, the display device 10 according to one or more embodiments may be variously classified according to a display method. For example, classification of the display device may include an organic light emitting display (OLED), an inorganic light emitting display (inorganic EL), a quantum dot light emitting display (QED), a micro LED display (micro-LED), a nano LED display (nano-LED), a plasma display panel (PDP), a field emission display (FED), a cathode ray tube display (CRT), a liquid crystal display (LCD), an electrophoretic display (EPD), and the like. Hereinafter, a micro LED display device will be described as an example of the display device, and unless a special distinction is required, a micro LED display device applied to an embodiment will be simply abbreviated as a display device. However, one or more embodiments are not limited to the micro LED display device, and other display devices listed above or known in the present technical field may also be applied within the scope of the present disclosure.

In addition, in the drawings, a first direction DR1 refers to a transverse direction of the display device 10, a second direction DR2 refers to a longitudinal direction of the display device 10, and a third direction DR3 refers to a thickness direction of the display device 10. In this case, “left”, “right”, “upper”, and “lower” refer to directions when the display device 10 is viewed in a plan view. For example, “right side” refers to one side in the first direction DR1, “left side” refers to the other side in the first direction DR1, “upper side” refers to one side in the second direction DR2, and “lower side” refers to the other side in the second direction DR2. In addition, “upper portion” refers to one side in the third direction DR3, and “lower portion” refers to the other side in the third direction DR3.

The display device 10 according to one or more embodiments may have a circular shape, an elliptical shape, or a quadrate shape in a plan view, and may have, for example, a square shape. In addition, when the display device 10 is a television, the display device 10 may have a rectangular shape of which long sides thereof are positioned in the transverse direction. However, the present disclosure is not limited thereto, and the long sides of the display device 1 may be positioned in a longitudinal direction or the display device 1 may be rotatably installed, such that the long sides of the display device 1 may be variably positioned in the transverse or longitudinal direction.

The display device 10 may include a display area DPA and non-display areas NDA. The display area DPA may be an active area in which an image is displayed. The display area DPA may have a square shape in a plan view, similar to the overall shape of the display device 10, but is not limited thereto, and may have a circular shape or an elliptical shape.

The display area DPA may include a plurality of pixels PX. The plurality of pixels PX may be arranged in a matrix direction. For example, the plurality of pixels PX may be arranged along rows and columns of a matrix. A shape of each pixel PX may be a rectangular shape or a square shape in a plan view, but is not limited thereto, and may also be a rhombic shape of which each side is inclined with respect to one side direction of the display device 10. The plurality of pixels PX may include several color pixels PX. For example, the plurality of pixels PX may include first color pixels PX, which are red pixels, second color pixels PX, which are green pixels, and third color pixels PX, which are blue pixels. The present disclosure is not limited thereto, and the plurality of pixels PX may further include fourth color pixels PX, which are white pixels. The respective color pixels PX may be alternately arranged in a stripe type or a PENTILE® structure, or the like. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

The non-display areas NDA may be disposed around the display area DPA along an edge or periphery of the display area DPA. The non-display areas NDA may entirely or partially surround the display area DPA. The display area DPA may have various shapes such as a circular shape or a square shape. The non-display area NDA may be formed to surround the periphery of the display area DPA according to the shape of the display area DPA. The non-display area NDA may be a bezel portion of the display device 10.

Driving circuits or driving elements for driving the display area DPA may be disposed in the non-display areas NDA. In one or more embodiments, in an area of the non-display area NDA that is disposed adjacent to a first side (lower side in FIG. 1) of the display device 10, a pad part may be provided on a display substrate of the display device 10, and external devices EXD may be mounted on pad electrodes of the pad part. Examples of the external devices EXD may include a connection film, a printed circuit board, a driving chip DIC, a connector, a wiring connection film, and the like. A scan driver SDR and the like formed on the display substrate of the display device 10 may be disposed in an area of the non-display area NDA that is disposed adjacent to a second side (left side in FIG. 1) of the display device 10.

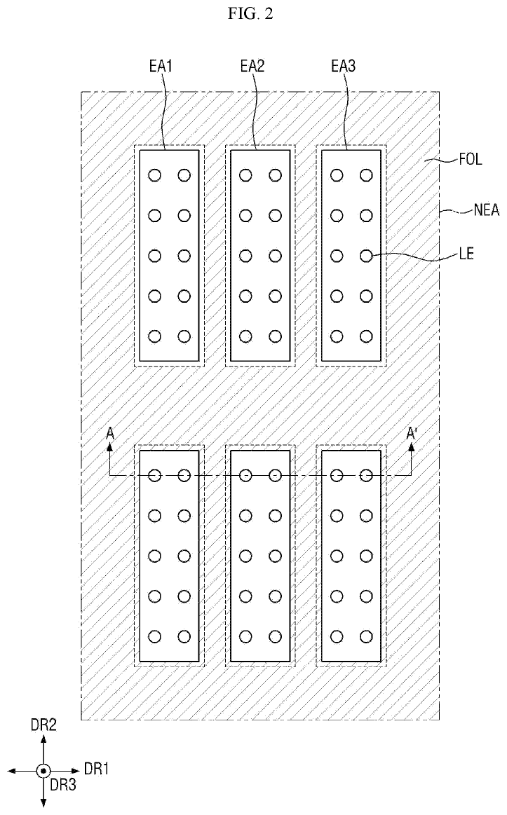

FIG. 2 is a schematic plan view illustrating emission areas of respective pixels according to one or more embodiments.

Referring to FIG. 2, the plurality of pixels PX may be arranged in a stripe type in the matrix direction, and may be divided into first color pixels PX, which are red pixels, second color pixels PX, which are green pixels, and third color pixels PX, which are blue pixels. In addition, the plurality of pixels PX may be divided to further include fourth color pixels PX, which are white pixels.

A pixel electrode of the first color pixel PX may be positioned in a first emission area EA1 of the first color pixel PX, and at least a portion thereof may extend to a non-emission area NEA. A pixel electrode of the second color pixel PX may be positioned in a second emission area EA2 of the second color pixel PX, and at least a portion thereof may extend to the non-emission area NEA. A pixel electrode of the third color pixel PX may be positioned in a third emission area EA3 of the third color pixel PX, and at least a portion thereof may extend to the non-emission area NEA. A pixel electrode of each of the pixels PX may penetrate through an insulating layer of at least one layer to be connected to any one switching element included in each pixel circuit.

A plurality of light emitting elements LE are disposed on the pixel electrode of the first emission area EA1, the pixel electrode of the second emission area EA2, and the pixel electrode of the third emission area EA3. That is, the light emitting elements LE are disposed in each of the first emission area EA1, the second emission area EA2, and the third emission area EA3. In addition, a first color filter, which is a red color filter, a second color filter, which is a green color filter, and a third color filter, which is a blue color filter, may be disposed, respectively, on the first emission area EA1, the second emission area EA2, and the third emission area EA3 in which the plurality of light emitting elements LE are disposed. A first organic layer FOL may be disposed in the non-emission area NEA.

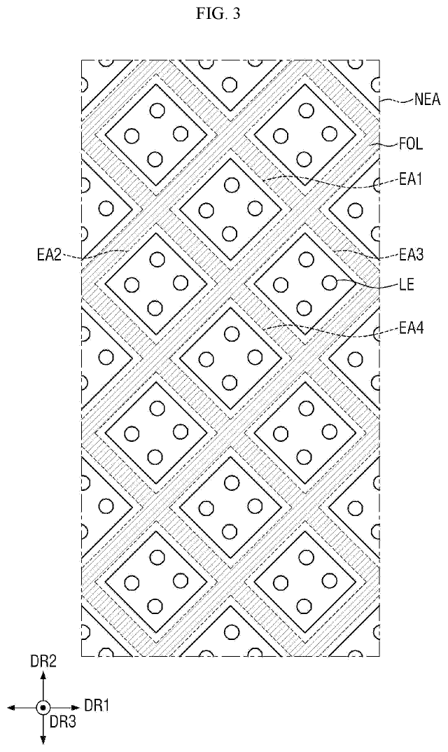

FIG. 3 is a schematic plan view illustrating emission areas of respective pixels according to one or more embodiments.

Referring to FIG. 3, a shape of each of the pixels PX is not limited to a rectangular shape or a square shape in a plan view, and may be a rhombic shape of which each side is inclined with respect to one side direction of the display device 10 so as to form a Pentile® matrix structure. Accordingly, in the respective pixels PX of the Pentile® matrix structure, each of a first emission area EA1 of the first color pixel PX, a second emission area EA2 of the second color pixel PX, a third emission area EA3 of the third color pixel PX, and a fourth emission area EA4 of a pixel PX of the same color as any one of first to third colors may be formed in a diamond shape.

Sizes or planar areas of the first to fourth emission areas EA1 to EA4 of each pixel PX may be the same as or different from each other. Similarly, the numbers of light emitting elements LE each disposed in the first to fourth emission areas EA1 to EA4 may be the same as or different from each other.

Specifically, an area of the first emission area EA1, an area of the second emission area EA2, an area of the third emission area EA3, and an area of the fourth emission area EA4 may be substantially the same as each other, but are not limited thereto, and may also be different from each other. A distance between the first emission area EA1 and the second emission area EA2 neighboring to each other, a distance between the second emission area EA2 and the fourth emission area EA4 neighboring to each other, a distance between the first emission area EA1 and the third emission area EA3 neighboring to each other, and a distance between the third emission area EA3 and the fourth emission area EA4 neighboring to each other may be substantially the same as each other, but may also be different from each other. One or more embodiments of the present disclosure are not limited thereto.

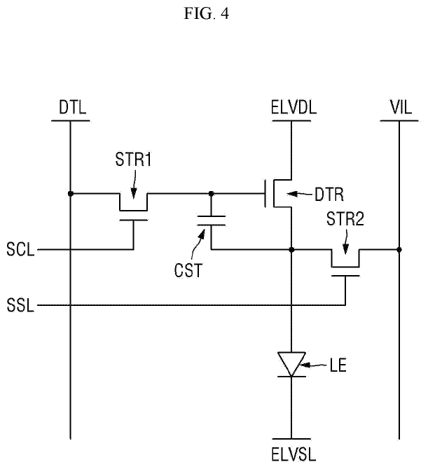

In addition, the first emission area EA1 may emit first color light, the second emission area EA2 may emit second color light, and the third emission area EA3 and the fourth emission area EA4 may emit third color light, but one or more embodiments of the present disclosure are not limited thereto. For example, the first emission area EA1 may emit the second color light, the second emission area EA2 may emit the first color light, and the third and fourth emission areas EA3 and EA4 may emit the third color light. Alternatively, the first emission area EA1 may emit the third color light, the second emission area EA2 may emit the second color light, and the third and fourth emission areas EA3 and EA4 may emit the first color light. Alternatively, at least one of the first to fourth emission areas EA1 to EA4 may emit fourth color light. The fourth color light may be light of a white or yellow wavelength band. As an example, a main peak wavelength of the fourth color light may be positioned at approximately 550 nm to 600 nm, but one or more embodiments of the present disclosure are not limited thereto. FIG. 4 is an equivalent circuit diagram of each pixel according to one or more embodiments.

Referring to FIG. 4, each pixel PX may include three transistors DTR, STR1, and STR2 for controlling the light emission of the light emitting elements LE and one storage capacitor CST. A driving transistor DTR adjusts a current flowing from a first power line ELVDL to which a first source voltage is supplied to any one light emitting element LE according to a voltage difference between a gate electrode and a source electrode thereof. The gate electrode of the driving transistor DTR may be connected to a first electrode of a first transistor STR1, the source electrode of the driving transistor DTR may be connected to the first electrode of any one light emitting element LE, and a drain electrode of the driving transistor DTR may be connected to the first power line ELVDL to which the first source voltage is applied.

The first transistor STR1 is turned on by a scan signal of a scan line SCL to connect a data line DTL to the gate electrode of the driving transistor DTR. A gate electrode of the first transistor STR1 may be connected to the scan line SCL, the first electrode of the first transistor STR1 may be connected to the gate electrode of the driving transistor DTR, and a second electrode of the first transistor STR1 may be connected to the data line DTL.

A second transistor STR2 is turned on by a sensing signal of a sensing signal line SSL to connect an initialization voltage line VIL to the source electrode of the driving transistor DTR. A gate electrode of the second transistor STR2 may be connected to the sensing signal line SSL, a first electrode of the second transistor STR2 may be connected to the initialization voltage line VIL, and a second electrode of the second transistor STR2 may be connected to the source electrode of the driving transistor DTR.

In one or more embodiments, the first electrode of each of the first and second transistors STR1 and STR2 may be a source electrode, and the second electrode of each of the first and second transistors STR1 and STR2 may be a drain electrode, but the present disclosure is not limited thereto, and vice versa.

The storage capacitor CST is formed between the gate electrode and the source electrode of the driving transistor DTR. The storage capacitor CST stores a difference voltage between a gate voltage and a source voltage of the driving transistor DTR.

The driving transistor DTR and the first and second transistors STR1 and STR2 may be formed as thin film transistors (TFT). In addition, it has been mainly described in FIG. 4 that the driving transistor DTR and the first and second transistors STR1 and STR2 are N-type metal oxide semiconductor field effect transistors (MOSFETs), but the present disclosure is not limited thereto. That is, the driving transistor DTR and the first and second transistors STR1 and STR2 may be P-type MOSFETs or some of the driving transistor DTR and the first and second transistors STR1 and STR2 may be N-type MOSFETs and the others of the driving transistor DTR and the first and second transistors STR1 and STR2 may be P-type MOSFETs.

The light emitting elements LE may be connected between the source electrode of the driving transistor DTR and a second power line ELVSL.

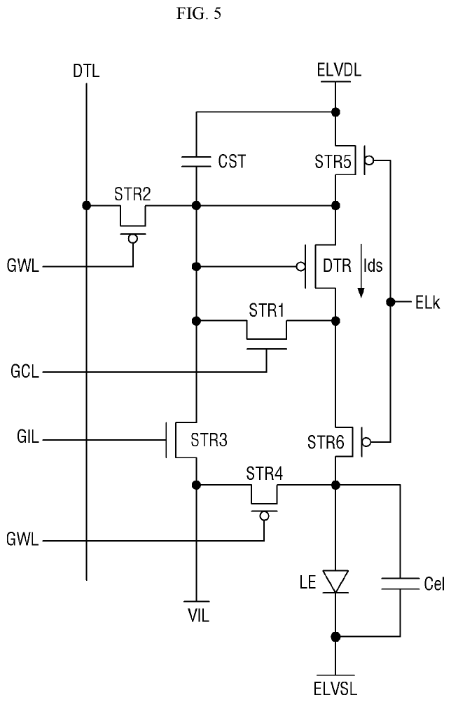

FIG. 5 is an equivalent circuit diagram of each pixel according to one or more embodiments.

Referring to FIG. 5, each pixel PX may include a plurality of switch elements and a driving transistor DTR for controlling the light emission of the light emitting elements LE and a capacitor CST. Here, the plurality of switch elements may include first to sixth transistors STR1, STR2, STR3, STR4, STR5, and STR6.

The driving transistor DTR includes a gate electrode, a first electrode, and a second electrode. The driving transistor DTR controls a drain-source current Ids (hereinafter, referred to as a “driving current”) flowing between the first electrode and the second electrode of the driving transistor DRT according to a data voltage applied to the gate electrode of the driving transistor DRT.

The capacitor CST is formed between the second electrode of the driving transistor DTR and a first power line ELVDL. One electrode of the capacitor CST may be connected to the second electrode of the driving transistor DTR, and the other electrode of the capacitor CST may be connected to the first power line ELVDL.

When a first electrode of each of the first to sixth transistors STR1, STR2, STR3, STR4, STR5, and STR6 and the driving transistor DTR is a source electrode, a second electrode of each of the first to sixth transistors STR1, STR2, STR3, STR4, STR5, and STR6 and the driving transistor DTR may be a drain electrode. Alternatively, when the first electrode of each of the first to sixth transistors STR1, STR2, STR3, STR4, STR5, and STR6 and the driving transistor DTR is a drain electrode, the second electrode of each of the first to sixth transistors STR1, STR2, STR3, STR4, STR5, and STR6 and the driving transistor DTR may be a source electrode.

The driving transistor DTR, the second transistor STR2, the fourth transistor STR4, the fifth transistor STR5, and the sixth transistor STR6 may be formed as P-type MOSFETs, and the first transistor STR1 and the third transistor STR3 may be formed as N-type MOSFETs. Alternatively, the first to sixth transistors STR1, STR2, STR3, STR4, STR5, and STR6 and the driving transistor DTR may be formed as P-type MOSFETs.

It is to be noted that the equivalent circuit diagram of the pixel according to one or more embodiments of the present disclosure described above is not limited to those illustrated in FIGS. 4 and 5. The equivalent circuit diagram of the pixel according to one or more embodiments of the present disclosure may be formed in other known circuit structures that may be adopted by one of ordinary skill in the art in addition to embodiments illustrated in FIGS. 4 and 5.

The first transistor STR1 is connected between the gate electrode and the second electrode of the driving transistor DTR. The gate electrode of the first transistor STR1 is connected to a gate control line GCL.

The second transistor STR2 is connected between the data line DTL and the first electrode of the driving transistor DTR. The gate electrode of the second transistor STR2 is connected to a gate write line GWL.

The third transistor STR3 is connected between the gate electrode of the driving transistor DTR and an initialization voltage line VIL. The gate electrode of the third transistor STR3 is connected to a gate initialization line GIL.

The fourth transistor STR4 is connected between a first electrode of the light emitting element LE and the initialization voltage line VIL. The gate electrode of the fourth transistor STR4 is connected to the gate write line GWL.

The fifth transistor STR5 is connected between the first electrode of the driving transistor DTR and the first power line ELVDL. The gate electrode of the fifth transistor STR5 is connected to an emission control line ELk.

The sixth transistor STR6 is connected between the second electrode of the driving transistor DTR and the first electrode of the light emitting element LE. The gate electrode of the sixth transistor STR6 is connected to an emission control line ELk.

The light emitting element LE is connected between the second electrode of the sixth transistor STR6 and a second power line ELVSL.

A capacitor Cel is connected between the first and second electrode of the light emitting element LE.

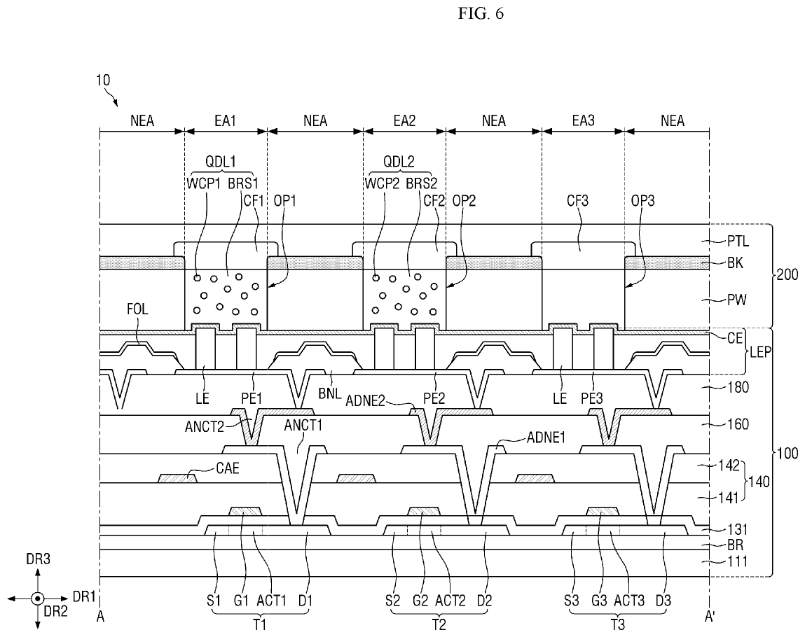

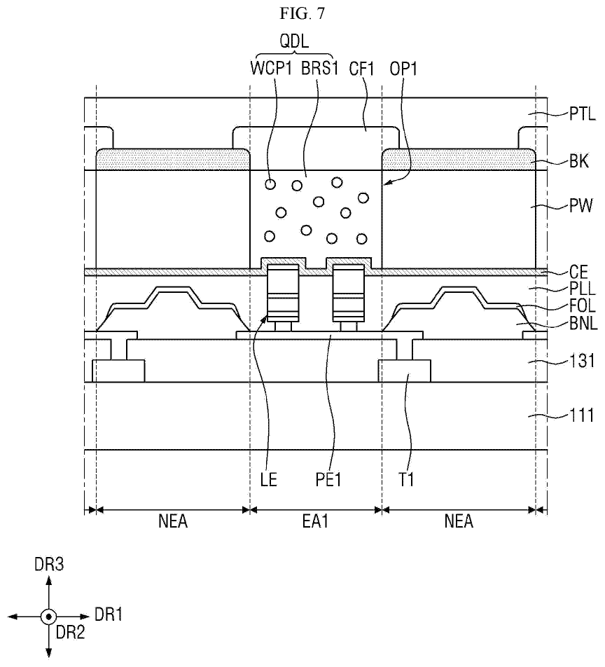

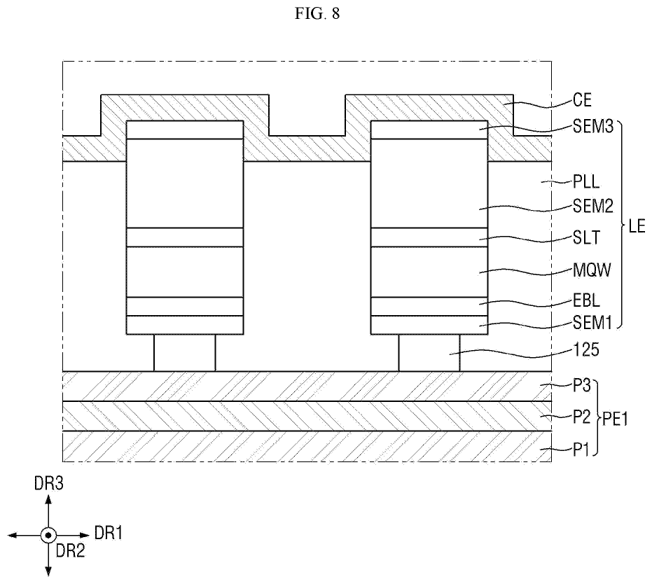

FIG. 6 is a schematic cross-sectional view according to one or more embodiments taken along the line A-A′ of FIG. 2. In addition, FIG. 7 is a schematic enlarged view illustrating a first emission area of FIG. 6, and FIG. 8 is a cross-sectional view illustrating a light emitting element of FIG. 7 in detail.

Referring to FIGS. 6 to 8, a display panel of the display device 10 may include a display substrate 101 and a wavelength conversion unit 201 disposed on the display substrate 101.

A barrier layer BR may be disposed on a first substrate 111 of the display substrate 101. The first substrate 111 may be made of an insulating material such as polymer resin. For example, the first substrate 111 may be made of polyimide. The first substrate 111 may be a flexible substrate that may be bent, folded, or rolled.

The barrier layer BR is a film for protecting thin film transistors T1, T2, and T3 and a light emitting element unit LEP from moisture penetrating through the first substrate 111 vulnerable to moisture permeation. The barrier layer BR may include a plurality of inorganic layers that are alternately stacked. For example, the barrier layer BR may be formed as multiple layers in which one or more inorganic layers of a silicon nitride layer, a silicon oxynitride layer, a silicon oxide layer, a titanium oxide layer, and/or an aluminum oxide layer are alternately stacked.

The respective transistors T1, T2, and T3 may be disposed on the barrier layer BR. The thin film transistors T1, T2, and T3 include active layers ACT1, ACT2, and ACT3, gate electrodes G1, G2, and G3, source electrodes S1, S2, and S3, and drain electrodes D1, D2, and D3, respectively.

The active layers ACT1, ACT2, and ACT3, the source electrodes S1, S2, and S3, and the drain electrodes D1, D2, and D3 of the thin film transistors T1, T2, and T3 may be disposed on the barrier layer BR. The active layers ACT1, ACT2, and ACT3 of the thin film transistors T1, T2, and T3 include polycrystalline silicon, single crystal silicon, low-temperature polycrystalline silicon, amorphous silicon, or an oxide semiconductor. The active layers ACT1, ACT2, and ACT3 overlapping the gate electrodes G1, G2, and G3 in the third direction (Z-axis direction), which is the thickness direction of the first substrate 111, may be defined as channel regions. The source electrodes S1, S2, and S3 and the drain electrodes D1, D2, and D3 are regions that do not overlap the gate electrodes G1, G2, and G3 in the third direction (Z-axis direction), and may have conductivity by doping a silicon semiconductor or an oxide semiconductor with ions or impurities.

A gate insulating layer 131 may be disposed on the active layers ACT1, ACT2, and ACT3, the source electrodes S1, S2, and S3, and the drain electrodes D1, D2, and D3 of the thin film transistors T1, T2, and T3. The gate insulating layer 131 may be formed as an inorganic layer such as a silicon nitride layer, a silicon oxynitride layer, a silicon oxide layer, a titanium oxide layer, and/or an aluminum oxide layer.

The gate electrodes G1, G2, and G3 of the thin film transistors T1, T2, and T3 may be disposed on the gate insulating layer 131. The gate electrodes G1, G2, and G3 may overlap the active layers ACT1, ACT2, and ACT3 in the third direction (Z-axis direction), respectively. Each of the gate electrodes G1, G2, and G3 may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A first interlayer insulating layer 141 may be disposed on the gate electrodes G1, G2, and G3 of the thin film transistors T1, T2, and T3. The first interlayer insulating layer 141 may be formed as an inorganic layer such as a silicon nitride layer, a silicon oxynitride layer, a silicon oxide layer, a titanium oxide layer, and/or an aluminum oxide layer. The first interlayer insulating layer 141 may be formed as a plurality of inorganic layers.

Capacitor electrodes CAE may be disposed on the first interlayer insulating layer 141. The capacitor electrodes CAE may or may not overlap the gate electrodes G1, G2, and G3 of the thin film transistors T1, T2, and T3 in the third direction (Z-axis direction). Because the first interlayer insulating layer 141 has a suitable dielectric constant (e.g., a predetermined dielectric constant), capacitors may be formed by the capacitor electrodes CAE, the gate electrodes G1, G2, and G3, and the first interlayer insulating layer 141 disposed between the capacitor electrodes CAE and the gate electrodes G1, G2, and G3. The capacitor electrode CAE may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A second interlayer insulating layer 142 may be disposed on the capacitor electrodes CAE. The second interlayer insulating layer 142 may be formed as an inorganic layer such as a silicon nitride layer, a silicon oxynitride layer, a silicon oxide layer, a titanium oxide layer, and/or an aluminum oxide layer. The second interlayer insulating layer 142 may be formed as a plurality of inorganic layers.

First anode connection electrodes ADNE1 may be disposed on the second interlayer insulating layer 142. The first anode connection electrodes ADNE1 may be respectively connected to the drain electrodes D1, D2, and D3 of the thin film transistors T1, T2, T3, through a first connection contact hole ANCT1 penetrating through the gate insulating layer 131, the first interlayer insulating layer 141, and the second interlayer insulating layer 142. The first anode connection electrode ADNE1 may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A first planarization layer 160 for planarizing a step due to the thin film transistors T1, T2, and T3 may be disposed on the first anode connection electrodes ADNE1. The first planarization layer 160 may be formed as an organic layer made of an acrylic resin, an epoxy resin, a phenolic resin, a polyamide resin, a polyimide resin, and/or the like.

Second anode connection electrodes ADNE2 may be disposed on the first planarization layer 160. The second anode connection electrode ADNE2 may be connected to the first anode connection electrode ADNE1 through a second connection contact hole ANCT2 penetrating through the first planarization layer 160. The second anode connection electrode ADNE2 may be formed as a single layer or multiple layers made of molybdenum (Mo), aluminum (Al), chromium (Cr), gold (Au), titanium (Ti), nickel (Ni), neodymium (Nd), and copper (Cu), and/or alloys thereof.

A second planarization layer 180 may be disposed on the second anode connection electrodes ADNE2. The second planarization layer 180 may be formed as an organic layer made of an acrylic resin, an epoxy resin, a phenolic resin, a polyamide resin, a polyimide resin, and/or the like.

The light emitting element unit LEP may be formed on the second planarization layer 180. The light emitting element unit LEP may include a plurality of pixel electrodes PE1, PE2, and PE3, a plurality of light emitting elements LE, and a common electrode CE.

The plurality of pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as first electrodes of the light emitting elements LE and may be anode electrodes or cathode electrodes. The first pixel electrode PE1 may be positioned in the first emission area EA1, and at least a portion thereof may extend to the non-emission area NEA. The second pixel electrode PE2 may be positioned in the second emission area EA2, and at least a portion thereof may extend to the non-emission area NEA. The third pixel electrode PE3 may be positioned in the third emission area EA3, and at least a portion thereof may extend to the non-emission area NEA. The first pixel electrode PE1 may penetrate through the second planarization layer 180 to be connected to a first switching element T1 via the second anode connection electrode ADNE2 and the first anode connection electrode ADNE1, the second pixel electrode PE2 may penetrate through the second planarization layer 180 to be connected to a second switching element T2 via the second anode connection electrode ADNE2 and the first anode connection electrode ADNE1, and the third pixel electrode PE3 may penetrate through the second planarization layer 180 to be connected to a third switching element T3 via the second anode connection electrode ADNE2 and the first anode connection electrode ADNE1.

The first pixel electrode PE1, the second pixel electrode PE2, and the third pixel electrode PE3 may be reflective electrodes. The first pixel electrode PE1, the second pixel electrode PE2, and the third pixel electrode PE3 may be made of titanium (Ti), copper (Cu), or an alloy of titanium (Ti), and/or copper (Cu). In addition, the first pixel electrode PE1, the second pixel electrode PE2, and the third pixel electrode PE3 may have a stacked layer structure of titanium (Ti) and copper (Cu). In addition, the first pixel electrode PE1, the second pixel electrode PE2, and the third pixel electrode PE3 may have a stacked layer structure in which a material layer having a high work function, made of titanium oxide (TiO₂), indium tin oxide (ITO), indium zinc oxide (IZO), zinc oxide (ZnO), indium tin zinc oxide (ITZO), and/or magnesium oxide (MgO) and a reflective material layer made of silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), and/or mixtures thereof are stacked. The material layer having the high work function may be disposed at a layer above the reflective material layer to be disposed close to the light emitting element LE. The first pixel electrode PE1, the second pixel electrode PE2, and the third pixel electrode PE3 may have a multilayer structure of ITO/Mg, ITO/MgF, ITO/Ag, and/or ITO/Ag/ITO, but are not limited thereto.

A bank BNL may be positioned on the first pixel electrode PE1, the second pixel electrode PE2, and the third pixel electrode PE3. The bank BNL may include an opening exposing the first pixel electrode PE1, an opening exposing the second pixel electrode PE2, and an opening exposing the third pixel electrode PE3, and may define the first emission area EA1, the second emission area EA2, the third emission area EA3, and the non-emission area NEA. That is, an area of the first pixel electrode PE1 exposed without being covered by the bank BNL may be the first emission area EA1. An area of the second pixel electrode PE2 exposed without being covered by the bank BNL may be the second emission area EA2. An area of the third pixel electrode PE3 exposed without being covered by the bank BNL may be the third emission area EA3. In addition, an area in which the bank BNL is positioned may be the non-emission area NEA.

The bank BNL may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, and/or benzocyclobutene (BCB).

In one or more embodiments, the bank BNL may not overlap color filters CF1, CF2, and CF3 of a wavelength conversion unit 201 and may overlap a light blocking member BK to be described later. In one or more embodiments, the bank BNL may completely overlap the light blocking member BK. In addition, in one or more embodiments, the bank BNL may overlap a first color filter CF1, a second color filter CF2, and a third color filter CF3.

The plurality of light emitting elements LE may be disposed on the first pixel electrode PE1, the second pixel electrode PE2, and the third pixel electrode PE3.

As illustrated in FIGS. 7 and 8, the light emitting element LE may be disposed in each of the first emission area EA1, the second emission area EA2, and the third emission area EA3. The light emitting element LE may be a vertical light emitting diode element extending to be elongated in the third direction DR3. That is, a length of the light emitting element LE in the third direction DR3 may be greater than a length of the light emitting element LE in a horizontal direction. The length in the horizontal direction refers to a length in the first direction DR1 or a length in the second direction DR2. For example, the length of the light emitting element LE in the third direction DR3 may be approximately 1 to 5 μm.

The light emitting element LE may be a micro light emitting diode element. The light emitting element LE may include a connection electrode 125, a first semiconductor layer SEM1, an electron blocking layer EBL, an active layer MQW, a superlattice layer SLT, a second semiconductor layer SEM2, and a third semiconductor layer SEM3 in the thickness direction of the display substrate 101, that is, the third direction DR3. The connection electrode 125, the first semiconductor layer SEM1, the electron blocking layer EBL, the active layer MQW, the superlattice layer SLT, the second semiconductor layer SEM2, and the third semiconductor layer SEM3 may be sequentially stacked in the third direction DR3.

The light emitting element LE may have a cylindrical shape, a disk shape, or a rod shape with a width greater than a height. However, the present disclosure is not limited thereto, and the light emitting element LE may have a shape such as a rod shape, a wire shape, or a tube shape, or a polygonal prismatic shape such as a cubic shape, a rectangular parallelepiped shape, or a hexagonal prismatic shape, or may have various shapes such as a shape in which it extends in one direction and has outer surfaces partially inclined.

The connection electrode 125 may be disposed on each of the plurality of pixel electrodes PE1, PE2, and PE3. Hereinafter, the light emitting element LE disposed on the first pixel electrode PE1 will be described by way of example.

The connection electrode 125 may be on the first pixel electrode PE1 to be connected to the first pixel electrode PE1, so that the light emitting element LE may receive a light emitting signal. The connection electrode 125 may be an ohmic connection electrode. However, the present disclosure is not limited thereto, and the connection electrode 125 may also be a Schottky connection electrode. The light emitting element LE may include at least one connection electrode 125. It has been illustrated in FIGS. 7 and 8 that the light emitting element LE includes one connection electrode 125, but the present disclosure is not limited thereto. In some cases, the light emitting element LE may include a larger number of connection electrodes 125 or the connection electrode 125 may be omitted. A description of a light emitting element LE to be provided later may be equally applied even though the number of connection electrodes 125 is changed or the light emitting element LE includes a different structure.

The connection electrode 125 may decrease a resistance between the light emitting element LE and the first pixel electrode PE1 and improve adhesiveness between the light emitting element LE and the first pixel electrode PE1, when the light emitting element LE is electrically connected to the first pixel electrode PE1 in the display device 10 according to one or more embodiments. The connection electrode 125 may include a conductive metal oxide. For example, the connection electrode 125 may be made of ITO. The connection electrode 125 is in direct contact with and connected to the first pixel electrode PE1 disposed therebelow, and may thus be made of the same material as the first pixel electrode PE1. In addition, the connection electrode 125 may selectively further include a reflective electrode made of a metal having high reflectivity, such as aluminum (Al) or a diffusion prevention layer including nickel (Ni). Accordingly, adhesiveness between the connection electrode 125 and the first pixel electrode PE1 may be improved, such that contact characteristics between the connection electrode 125 and the first pixel electrode PE1 may be increased.

Referring to FIG. 8, in one or more embodiments, the first pixel electrode PE1 may include a lower electrode layer P1, a reflective layer P2, and an upper electrode layer P3. The lower electrode layer P1 may be disposed at the lowermost portion of the first pixel electrode PE1 and may be electrically connected from a switching element. The lower electrode layer P1 may include a metal oxide such as titanium oxide (TiO₂), indium tin oxide (ITO), indium zinc oxide (IZO), zinc oxide (ZnO), indium tin zinc oxide (ITZO), and/or magnesium oxide (MgO).

The reflective layer P2 may be disposed on the lower electrode layer P1 and reflect light emitted from the light emitting element LE upward. The reflective layer P2 may include a metal having a high reflectivity, such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), and/or mixtures thereof.

The upper electrode layer P3 may be disposed on the reflective layer P2 and may be in direct contact with the light emitting element LE. The upper electrode layer P3 may be disposed between the reflective layer P2 and the connection electrode 125 of the light emitting element LE to be in direct contact with the connection electrode 125. As described above, the connection electrode 125 may be made of the metal oxide, and the upper electrode layer P3 may also be made of a metal oxide, similar to the connection electrode 125.

The upper electrode layer P3 may be made of titanium (Ti), copper (Cu), or an alloy of titanium (Ti) and copper (Cu). In addition, the upper electrode layer P3 may have a stacked layer structure of titanium (Ti) and/or copper (Cu). In addition, the upper electrode layer P3 may include titanium oxide (TiO₂), indium tin oxide (ITO), indium zinc oxide (IZO), zinc oxide (ZnO), indium tin zinc oxide (ITZO), and/or magnesium oxide (MgO). In one or more embodiments, when the connection electrode 125 is made of ITO, the first pixel electrode PE1 may have a multilayer structure of ITO/Ag/ITO.

The first semiconductor layer SEM1 may be disposed on the connection electrode 125. The first semiconductor layer SEM1 may be a p-type semiconductor, and may include a semiconductor material having a chemical formula of AlₓGa_{y}In_{1-x-y}N (0≤x≤1, 0≤y≤1, and 0≤x+y≤1). For example, the semiconductor material may be one or more of AlGaInN, GaN, AlGaN, InGaN, AlN, and/or InN doped with a p-type dopant. The first semiconductor layer SEM1 may be doped with a p-type dopant, which may be Mg, Zn, Ca, Se, Ba, or the like. For example, the first semiconductor layer SEM1 may be made of p-GaN doped with p-type Mg. A thickness of the first semiconductor layer SEM1 may be in the range of 30 nm to 200 nm, but is not limited thereto.

The electron blocking layer EBL may be disposed on the first semiconductor layer SEM1. The electron blocking layer EBL may be a layer for suppressing or preventing too many electrons from flowing to the active layer MQW. For example, the electron blocking layer EBL may be made of p-AlGaN doped with p-type Mg. A thickness of the electron blocking layer EBL may be in the range of 10 nm to 50 nm, but is not limited thereto. In addition, the electron blocking layer EBL may be omitted. The active layer MQW may be disposed on the electron blocking layer EBL.

The active layer MQW may emit light by a combination of electron-hole pairs according to electrical signals applied through the first semiconductor layer SEM1 and the second semiconductor layer SEM2.

The active layer MQW may include a material having a single or multiple quantum well structure. When the active layer MQW includes the material having the multiple quantum well structure, the active layer MQW may have a structure in which a plurality of well layers and barrier layers are alternately stacked. In this case, the well layer may be made of InGaN, and the barrier layer may be made of GaN or AlGaN, but the present disclosure is not limited thereto. A thickness of the well layer may be approximately 1 to 4 nm, and a thickness of the barrier layer may be 3 nm to 10 nm.

Alternatively, the active layer MQW may have a structure in which semiconductor materials having large band gap energy and semiconductor materials having small band gap energy are alternately stacked, and may include other Group III to Group V semiconductor materials depending on a wavelength band of emitted light. The light emitted by the active layer MQW is not limited to first light, and in some cases, the active layer MQW may emit second light (e.g., light of a green wavelength band) or third light (e.g., light of a red wavelength band).

Specifically, a color of the light emitted from the active layer MQW may change depending on a content of indium (In). For example, as the content of indium (In) increases, a wavelength band of the light emitted by the active layer may move to a red wavelength band, and as the content of indium (In) decreases, a wavelength band of the light emitted by the active layer may move to a blue wavelength band. For example, when the content of indium (In) is 35% or more, the active layer MQW may emit first light of a red wavelength band having a main peak wavelength in the range of approximately 600 nm to 750 nm. In contrast, when the content of indium (In) is 25%, the active layer MQW may emit second light of a green wavelength band having a main peak wavelength in the range of approximately 480 nm to 560 nm. In contrast, when the content of indium (In) is less than 15%, the active layer MQW may emit third light of a blue wavelength band having a main peak wavelength in the range of approximately 370 nm to 460 nm. An example in which the active layer MQW emits light of a blue wavelength band having a main peak wavelength in the range of approximately 370 nm to 460 nm will be described with reference to FIG. 6.

The superlattice layer SLT may be disposed on the active layer MQW. The superlattice layer SLT may be a layer for alleviating stress between the second semiconductor layer SEM2 and the active layer MQW. For example, the superlattice layer SLT may be made of InGaN and/or GaN. A thickness of the superlattice layer SLT may be approximately 50 to 200 nm. The superlattice layer SLT may be omitted. The second semiconductor layer SEM2 may be disposed on the superlattice layer SLT. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, and 0≤x+y≤1). For example, the semiconductor material may be one or more of AlGaInN, GaN, AlGaN, InGaN, AlN, and/or InN doped with an n-type dopant. The second semiconductor layer SEM2 may be doped with an n-type dopant, which may be Si, Ge, Sn, or the like. For example, the second semiconductor layer SEM2 may be made of n-GaN doped with n-type Si. A thickness of the second semiconductor layer SEM2 may be in the range of 2 μm to 4 μm, but is not limited thereto.

The third semiconductor layer SEM3 may be disposed on the second semiconductor layer SEM2. The third semiconductor layer SEM3 may be disposed between the second semiconductor layer SEM2 and the common electrode CE. The third semiconductor layer SEM3 may be an undoped semiconductor. The third semiconductor layer SEM3 may include a material that is the same as that of the second semiconductor SEM2, but is not doped with an n-type or p-type dopant. In one or more embodiments, the third semiconductor layer SEM3 may be made of at least one of undoped InAlGaN, GaN, AlGaN, InGaN, AlN, and/or InN, but is not limited thereto.

A planarization layer PLL may be disposed on the bank BNL and the plurality of pixel electrodes PE1, PE2, and PE3. The planarization layer PLL may planarize a step of a lower portion so that a common electrode CE to be described later may be formed. The planarization layer PLL may be formed to have a suitable height (e.g., a predetermined height) so that at least portions, for example, upper portions of the plurality of light emitting elements LE, may protrude above the planarization layer PLL. That is, on the basis of an upper surface of the first pixel electrode PE1, a height of the planarization layer PLL may be smaller than a height of the light emitting element LE in the third direction DR3.

The planarization layer PLL may include an organic material so as to planarize the step of the lower portion. For example, the planarization layer PLL may include a polyacrylates resin, an epoxy resin, a phenolic resin, a polyamides resin, a polyimides resin, an unsaturated polyesters resin, a polyphenyleneethers resin, a polyphenylenesulfides resin, benzocyclobutene (BCB), or the like.

The common electrode CE may be disposed on the planarization layer PLL and the plurality of light emitting elements LE. Specifically, the common electrode CE may be disposed on one surface of the first substrate 111 on which the light emitting elements LE are formed, and may be disposed throughout the display area DA and the non-display area NDA. The common electrode CE may be disposed to overlap each of the emission areas EA1, EA2, and EA3 in the display area DA, and may be formed to have a small thickness so that light may be emitted.

The common electrode CE may be directly disposed on upper surfaces and side surfaces of the plurality of light emitting elements LE. The common electrode CE may be in direct contact with the second semiconductor layer SEM2 on the side surfaces of the light emitting element LE and the third semiconductor layer SEM3 on the top surface and the side surfaces of the light emitting element LE. As illustrated in FIG. 6, the common electrode CE may be a common layer covering the plurality of light emitting elements LE and disposed to connect the plurality of light emitting elements LE to each other in common. Because the second semiconductor layers SEM2 having conductivity have a structure in which they are each patterned in the light emitting elements LE, the common electrode CE may be in direct contact with side surfaces of the second semiconductor layer SEM2 of each light emitting element LE so that a common voltage may be applied to each light emitting element LE.

Because the common electrode CE is entirely disposed on the first substrate 111 and the common voltage is applied to the common electrode CE, the common electrode CE may include a material having a low resistance. In addition, the common electrode CE may be formed to have a small thickness so as to easily transmit light therethrough. For example, the common electrode CE may include a material having a low resistance, such as aluminum (Al), silver (Ag), and/or copper (Cu). A thickness of the common electrode CE may be approximately 10 Å to 200 Å, but is not limited thereto.

The above-described light emitting elements LE may receive pixel voltages or the anode voltages of the pixel electrodes supplied through the connection electrodes 125 and receive the common voltage supplied through the common electrode CE. The light emitting element LE may emit light with a desired luminance (e.g., a predetermined luminance) according to a voltage difference between the pixel voltage and the common voltage.

In the described embodiment, by disposing the plurality of light emitting elements LE, that is, inorganic light emitting diodes, on the pixel electrodes PE1, PE2, and PE3, it is possible to eliminate a disadvantage of organic light emitting diodes vulnerable to external moisture or oxygen and improve lifespan and reliability of the light emitting elements LE.

In one or more embodiments, the first organic layer FOL may be disposed on the bank BNL disposed in the non-emission area NEA.

The first organic layer FOL may be disposed to overlap the non-emission area NEA in the third direction DR3 and not overlap the emission areas EA1, EA2, and EA3. The first organic layer FOL may be directly disposed on the bank BNL and may be disposed to be spaced from the plurality of pixel electrodes PE1, PE2, and PE3 adjacent thereto. The first organic layer FOL may be entirely disposed on the first substrate 111, and may be disposed to be around (e.g., to surround) the plurality of emission areas EA1, EA2, and EA3. The first organic layer FOL may be disposed in a lattice shape as a whole.

The first organic layer FOL may serve to detach the plurality of light emitting elements LE in contact with the first organic layer FOL, which is the non-emission area NEA, from the first organic layer FOL, as described in a fabricating process to be described later. When the first organic layer FOL is irradiated with laser light, the first organic layer FOL absorbs energy, such that a temperature of the first organic layer FOL instantaneously rises, and thus, the first organic layer FOL is ablated. Accordingly, the plurality of light emitting elements LE in contact with an upper surface of the first organic layer FOL may be detached from the upper surface of the first organic layer FOL.

The first organic layer FOL may include a polyimides compound. The polyimides compound of the first organic layer FOL may include a cyano group so as to be able to absorb light having a wavelength of 308 nm, for example, laser light. In one or more embodiments, the first organic layer FOL and the bank BNL may each include a polyimides compound, but may include different polyimides compounds. For example, the bank BNL may be made of a polyimides compound that does not include a cyano group, and the first organic layer FOL may be made of a polyimides compound that includes a cyano group. With respect to the laser light having the wavelength of 308 nm, transmissivity of the first organic layer FOL may be smaller than that of the bank BNL, the transmissivity of the bank BNL may be about 60% or more, and the transmissivity of the first organic layer FOL may be 0%. In addition, absorptivity of the first organic layer FOL for the laser light having the wavelength of 308 nm may be 100%. The first organic layer FOL may have a thickness in the range of about 2 Å to about 10 μm. When the thickness of the first organic layer FOL is 2 Å or more, the absorptivity of the laser light having the wavelength of 308 nm may be improved. When the thickness of the first organic layer FOL is 10 μm or less, an increase in a step between the first organic layer FOL and the pixel electrode PE1 may be prevented, such that the light emitting element LE may be easily adhered onto the pixel electrode in a process to be described later.

The wavelength conversion unit 201 may be disposed on the light emitting element unit LEP. The wavelength conversion unit 201 may include a partition wall PW, wavelength conversion layers QDL, color filters CF1, CF2, and CF3, the light blocking member BK, and a passivation layer PTL.

The partition wall PW may be disposed on the common electrode CE of the display area DPA, and may partition a plurality of emission areas EA1, EA2, and EA3 together with the bank BNL. The partition wall PW may be disposed to extend in the first direction DR1 and the second direction DR2, and may be formed in a lattice pattern throughout the display area DA. In addition, the partition wall PW may not overlap the plurality of emission areas EA1, EA2, and EA3, and may overlap the non-emission areas NEA.

The partition wall PW may include a plurality of openings OP1, OP2, and OP3 exposing the common electrode CE disposed therebelow. The plurality of openings OP1, OP2, and OP3 may include a first opening OP1 overlapping the first emission area EA1, a second opening OP2 overlapping the second emission area EA2, and a third opening OP3 overlapping the third emission area EA3. Here, the plurality of openings OP1, OP2, and OP3 may correspond to the plurality of emission areas EA1, EA2, and EA3. That is, the first opening OP1 may correspond to the first emission area EA1, the second opening OP2 may correspond to the second emission area EA2, and the third opening OP3 may correspond to the third emission area EA3.

The partition wall PW may serve to provide spaces in which first and second wavelength conversion layers QDL1 and QDL2 are to be formed. To this end, the partition wall PW may be formed to have a suitable thickness (e.g., a predetermined thickness), for example, a thickness in the range of 1 μm to 10 μm. The partition wall PW may include an organic insulating material so as to have a suitable thickness (e.g., a predetermined thickness). The organic insulating material may include, for example, an epoxy-based resin, an acrylic resin, a cardo-based resin, and/or an imide-based resin.

The first wavelength conversion layer QDL1 may be disposed in the first opening OP1. The first wavelength conversion layer QDL1 may include dot-shaped island patterns spaced from each other. The first wavelength conversion layer QDL1 may include a first base resin BRS1 and first wavelength conversion particles WCP1. The first base resin BRS1 may include a light-transmitting organic material. For example, the first base resin BRS1 may include an epoxy-based resin, an acrylic resin, a cardo-based resin, an imide-based resin, or the like. The first wavelength conversion particle WCP1 may be a quantum dot (QD), a quantum rod, a fluorescent material, or a phosphorescent material. For example, the quantum dot may be a particulate matter emitting a specific color while electrons are transitioning from a conduction band to a valence band.

The quantum dot may be a semiconductor nanocrystal material. The quantum dot may have a specific bandgap according to its composition and size to absorb light and then emit light having a unique wavelength. Examples of semiconductor nanocrystals of the quantum dot may include Group IV nanocrystals, Group II-VI compound nanocrystals, Group III-V compound nanocrystals, Group IV-VI compound nanocrystals, and/or combinations thereof.

The first wavelength conversion layer QDL1 may be formed in the first opening OP1 of the first emission area EA1. The first wavelength conversion layer QDL1 may convert or shift a peak wavelength of incident light into light having another specific peak wavelength and emit the light having another specific peak wavelength. The first wavelength conversion layer QDL1 may convert some of blue light emitted from the light emitting elements LE into light similar to red light, which is the first light. The first wavelength conversion layer QDL1 may emit the light similar to the red light to allow the light similar to the red light to be converted into the red light, which is the first light, through the first color filter CF1.

The second wavelength conversion layer QDL2 may be disposed in the second opening OP2. The second wavelength conversion layer QDL2 may include dot-shaped island patterns spaced from each other. For example, the second wavelength conversion layer QDL2 may be disposed to overlap the second emission area EA2. The second wavelength conversion layer QDL2 may include a second base resin BRS2 and second wavelength conversion particles WCP2. The second base resin BRS2 may include a light-transmitting organic material. Accordingly, the second wavelength conversion layer QDL2 may convert or shift a peak wavelength of incident light into light having another specific peak wavelength and emit the light having another specific peak wavelength. The second wavelength conversion layer QDL2 may convert some of blue light emitted from the light emitting elements LE into light similar to green light, which is the second light. The second wavelength conversion layer QDL2 may emit the light similar to the green light to allow the light similar to the green light to be converted into the green light, which is the second light, through the second color filter CF2.

In the third emission area EA3, only a transparent light-transmitting organic material may be formed in the third opening OP3 to allow blue light emitted from the light emitting elements LE to be emitted through the third color filter CF3 as it is. A plurality of color filters CF1, CF2, and CF3 may be disposed on the partition wall PW and the first and second wavelength conversion layers QDL1 and QDL2. The plurality of color filters CF1, CF2, and CF3 may be disposed to overlap the plurality of openings OP1, OP2, and OP3 and the first and second wavelength conversion layers QDL1 and QDL2, respectively. The plurality of color filters CF1, CF2, and CF3 may include the first color filter CF1, the second color filter CF2, and the third color filter CF3.

The first color filter CF1 may be disposed to overlap the first emission area EA1. In addition, the first color filter CF1 may be disposed on the first opening OP1 of the partition wall PW so as to overlap the first opening OP1. The first color filter CF1 may transmit the first light emitted from the light emitting elements LE therethrough and absorb or block the second light and the third light. For example, the first color filter CF1 may transmit light of a blue wavelength band therethrough and absorb or block light of other wavelength bands such as green and red wavelength bands.

The second color filter CF2 may be disposed to overlap the second emission area EA2. In addition, the second color filter CF2 may be disposed on the second opening OP2 of the partition wall PW so as to overlap the second opening OP2. The second color filter CF2 may transmit the second light therethrough and absorb or block the first light and the third light. For example, the second color filter CF2 may transmit light of a green wavelength band therethrough and absorb or block light of other wavelength bands such as blue and red wavelength bands.

The third color filter CF3 may be disposed to overlap the third emission area EA3. In addition, the third color filter CF3 may be disposed on the third opening OP3 of the partition wall PW so as to overlap the third opening OP3. The third color filter CF3 may transmit the third light therethrough and absorb or block the first light and the second light. For example, the third color filter CF3 may transmit light of a red wavelength band therethrough and absorb or block light of other wavelength bands such as blue and green wavelength bands.

An area of each of the plurality of color filters CF1, CF2, and CF3 in a plan view may be greater than an area of each of the plurality of emission areas EA1, EA2, and EA3 in a plan view. For example, the first color filter CF1 may have a greater area than the first emission area EA1 in a plan view. The second color filter CF2 may have a greater area than the second emission area EA2 in a plan view. The third color filter CF3 may have a greater area than the third emission area EA3 in a plan view. However, the present disclosure is not limited thereto, and the area of each of the plurality of color filters CF1, CF2, and CF3 in a plan view may also be the same as the area of each of the plurality of emission areas EA1, EA2, and EA3 in a plan view.

Referring to FIG. 6, the light blocking member BK may be disposed on the partition wall PW. The light blocking member BK may overlap the non-emission areas NEA to block transmission of the light. The light blocking member BK may be disposed in an approximately lattice shape in a plan view, similar to the bank BNL or the partition wall PW. The light blocking member BK may be disposed to overlap the bank BNL, the first organic layer FOL, and the partition wall PW, and may not overlap the emission areas EA1, EA2, and EA3.

In one or more embodiments, the light blocking member BK may include an organic light blocking material, and may be formed by a coating process, an exposing process, and the like, of the organic light blocking material. The light blocking member BK may include a dye or a pigment having light blocking properties, and may be a black matrix. At least portions of the light blocking member BK may overlap the color filters CF1, CF2, and CF3 adjacent thereto, and the color filters CF1, CF2 and CF3 may be disposed on at least portions of the light blocking member BK.

The passivation layer PTL may be disposed on the plurality of color filters CF1, CF2, and CF3 and the light blocking member BK. The passivation layer PTL may be disposed at the uppermost portion of the display device 10 to protect the plurality of color filters CF1, CF2, CF3 and the light blocking member BK disposed therebelow. One surface, for example, a lower surface of the passivation layer PTL may be in contact with each of upper surfaces of the plurality of color filters CF1, CF2, CF3 and the light blocking member BK.

The passivation layer PTL may include an inorganic insulating material in order to protect the plurality of color filters CF1, CF2, and CF3 and the light blocking member BK. For example, the passivation layer PTL may include silicon oxide (SiOₓ), silicon nitride (SiNₓ), silicon oxynitride (SiOₓN_{y}), aluminum oxide (AlₓO_{y}), aluminum nitride (AlN), and/or the like, but is not limited thereto. The passivation layer PTL may be formed to have a suitable thickness (e.g., a predetermined thickness), for example, a thickness in the range of 0.01 to 1 μm. However, the present disclosure is not limited thereto.

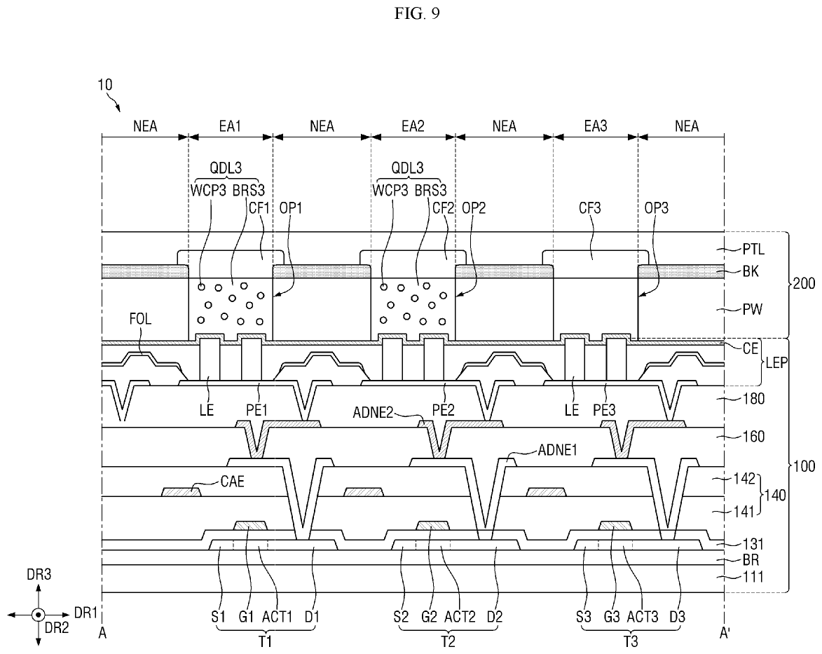

FIG. 9 is a schematic cross-sectional view according to one or more embodiments taken along the line A-A′ of FIG. 2.

Referring to FIG. 9, third wavelength conversion layers QDL3 may be disposed in the first and second openings OP1 and OP2, respectively.

The third wavelength conversion layers QDL3 may convert or shift a peak wavelength of incident light into light having another specific peak wavelength and emit the light having another specific peak wavelength. The third wavelength conversion layers QDL3 may convert some of the first light, which is the blue light, emitted from the light emitting elements LE into fourth light, which is yellow light. The third wavelength conversion layers QDL3 may mix the first light with the fourth light to emit fifth light, which is white light. The fifth light is converted into the first light through the first color filter CF1 and converted into the second light through the second color filter CF2.

The third wavelength conversion layers QDL3 may be disposed on the first and second openings OP1 and OP2, respectively, and may be spaced from each other. That is, the third wavelength conversion layers QDL3 may include dot-shaped island patterns spaced from each other. For example, the third wavelength conversion layers QDL3 may be disposed only in the first opening OP1 and the second opening OP2, respectively, and may correspond to the first opening OP1 and the second opening OP2 in a one-to-one manner. In addition, the third wavelength conversion layers QDL3 may be disposed to overlap the first emission area EA1 and the second emission area EA2 respectively. In one or more embodiments, the third wavelength conversion layers QDL3 may completely overlap the first emission area EA1 and the second emission area EA2, respectively.

The third wavelength conversion layer QDL3 may include a third base resin BRS3 and third wavelength conversion particles WCP3. The third base resin BRS3 may include a light-transmitting organic material. For example, the third base resin BRS3 may include an epoxy-based resin, an acrylic resin, a cardo-based resin, an imide-based resin, and/or the like.

The third wavelength conversion particles WCP3 may convert the first light incident from the light emitting elements LE into the fourth light. For example, the third wavelength conversion particles WCP3 may convert light of a blue wavelength band into light of a yellow wavelength band. The third wavelength conversion particle WCP3 may be a quantum dot (QD), a quantum rod, a fluorescent material, or a phosphorescent material. For example, the quantum dot may be a particulate matter emitting a specific color while electrons are transitioning from a conduction band to a valence band.

As a thickness of the third wavelength conversion layer QDL3 in the third direction DR3 increases, a content of the third wavelength conversion particles WCP3 included in the third wavelength conversion layer QDL3 increases, and light conversion efficiency of the third wavelength conversion layer QDL3 may thus increase. Therefore, the thickness of the third wavelength conversion layer QDL3 is preferably set in consideration of the light conversion efficiency of the third wavelength conversion layer QDL3.

In the third wavelength conversion layers QDL3 described above, some of the first light emitted from the light emitting elements LE may be converted into the fourth light. The third wavelength conversion layers QDL3 may mix the first light with the fourth light to emit the fifth light, which is the white light. Only a component of the first light in the fifth light emitted from the third wavelength conversion layer QDL3 may be transmitted through the first color filter CF1, and only a component of the second light in the fifth light may be transmitted through the second color filter CF2. Accordingly, the light emitted from the wavelength conversion unit 201 may be the red light, which is the first light, and the green light, which is the second light. In the third emission area EA3, only a transparent light-transmitting organic material may be formed in the third opening OP3 to allow blue light emitted from the light emitting elements LE to be emitted through the third color filter CF3 as it is. Accordingly, full color may be implemented.

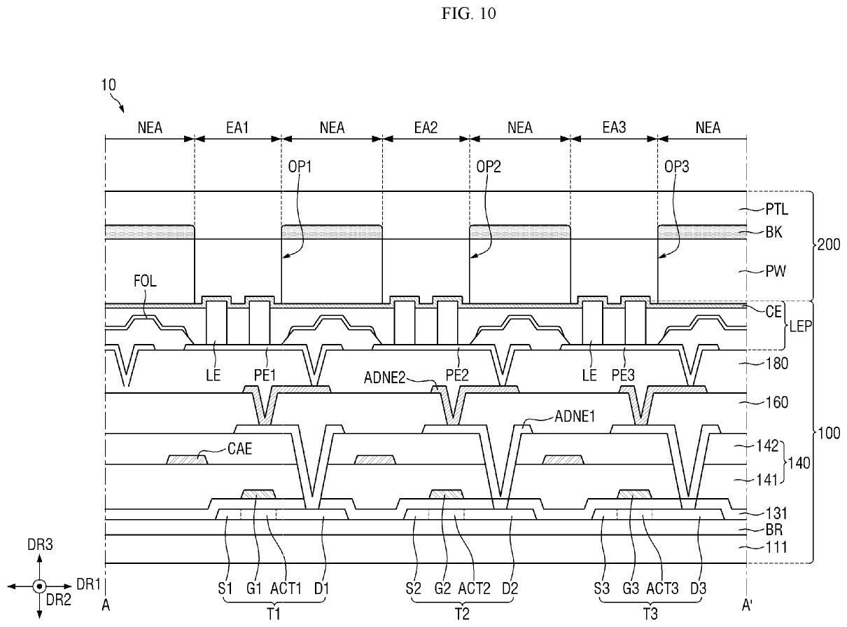

FIG. 10 is a schematic cross-sectional view according to still another embodiment taken along the line A-A′ of FIG. 2.

As described above, a color of the light emitted from the active layer MQW of each light emitting element LE may change depending on a content of indium (In). As the content of indium (In) increases, a wavelength band of the light emitted by the active layer may move to a red wavelength band, and as the content of indium (In) decreases, a wavelength band of the light emitted by the active layer may move to a blue wavelength band. Therefore, when the content of indium (In) in the active layer MQW of each light emitting element LE formed in the first emission area EA1 is 25% or more, the active layer MQW may emit the first light of the red wavelength band having a main peak wavelength of approximately 600 nm to 750 nm.

When the content of indium (In) in the active layer MQW of each light emitting element LE formed in the second emission area EA2 is 25%, the active layer MQW may emit the second light of the green wavelength band having a main peak wavelength of approximately 480 nm to 560 nm.

When the content of indium (In) in the active layer MQW of each light emitting element LE formed in the third emission area EA3 is less than 15%, the active layer MQW may emit the third light of the blue wavelength band having a main peak wavelength of approximately 370 nm to 460 nm.

Each light emitting element LE formed in the first emission area EA1 may emit the first light of the red wavelength band, each light emitting element LE formed in the second emission area EA2 may emit the second light of the green wavelength band, and each light emitting element LE formed in the third emission area EA3 may emit the third light of the blue wavelength band. In this case, the color filters CF1, CF2, and CF3 may not be formed.

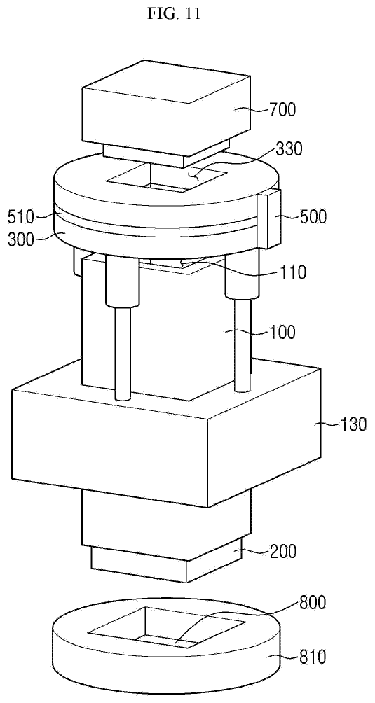

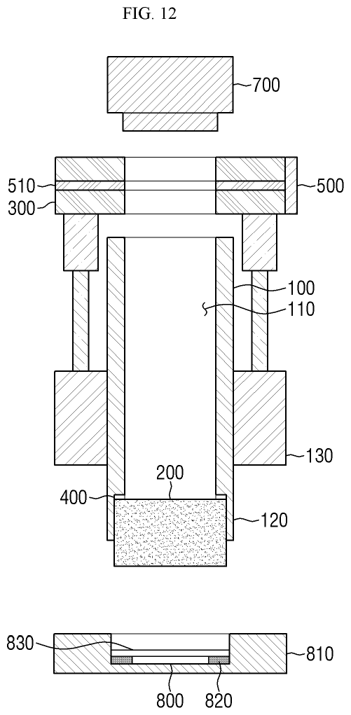

FIG. 11 is a schematic perspective view illustrating an apparatus for fabricating a display panel according to one or more embodiments. In addition, FIG. 12 is a cross-sectional view illustrating a cross-sectional structure of the apparatus for fabricating a display panel illustrated in FIG. 11.

Referring to FIGS. 11 and 12, an apparatus for fabricating a display panel includes an attachment member 100, a pressurization header 200, a fixing frame 130, an attachment driving member 300, a first pressure sensing module 400, a gradient setting module 500, a gradient control module 510, a laser irradiation member 700, and a second pressure sensing module 800.

The attachment member 100 is formed in a polyprismatic shape or a cylindrical shape in which an opening 110 having a polygonal shape such as a quadrangular shape, a circular shape, or the like, is formed, and the pressurization header 200 is coupled and fixed to a fixing part 120 formed in a pressurization direction in which the attachment member 100 moves. Hereinafter, an example in which the attachment member 100 is formed in a quadrangular prismatic shape in which an opening 110 having a quadrangular shape is formed will be described. In addition, the attachment member 100 may be disposed in a vertical direction from the ground, and a downward direction toward the ground may be a pressurization direction of the attachment member 100. On the contrary, an upward direction opposite to a direction toward the ground may be a detachment direction of the attachment member 100.

The fixing part 120 into which the pressurization header 200 is inserted and fixed is formed at one end of the attachment member 100 disposed in the pressurization direction, which is the downward direction. An insertion hole into which the pressurization header 200 is inserted and fixed is formed in the fixing part 120 of the attachment member 100. The insertion hole may be a polygonal hole such as a quadrangular hole, a cylindrical hole, or the like, formed according to a shape of an outer surface (e.g., an outer peripheral or circumferential surface) of the pressurization header 200. Thus, an upper surface of the pressurization header 200 and an outer surface (e.g., an outer peripheral or circumferential surface) of the pressurization header 200 in a lateral direction may be inserted and fixed into the insertion hole formed in the fixing part 120 of the attachment member 100.

As illustrated in FIG. 12, an inner diameter of the insertion hole into which the pressurization header 200 is inserted may be greater than an inner diameter of the opening itself of the attachment member 100. An inner width of the insertion hole may be greater than an inner width of the opening of the attachment member 100. Accordingly, an inner step is formed in the fixing part 120 according to a difference in inner diameter between the opening of the attachment member 100 and the insertion hole.

The first pressure sensing module 400 may be disposed on the inner step of the fixing part 120. The first pressure sensing module 400 may be formed in a quadrangular ring or O-ring shape corresponding to a shape and an area of the inner step of the fixing part 120. Alternatively, the first pressure sensing module 400 may be separated into a plurality of pieces, and the plurality of pieces of the first pressure sensing module 400 may be separately disposed on an inner step surface of the fixing part 120. The pressurization header 200 may be inserted and fixed into the insertion hole of the fixing part 120 in a state in which the first pressure sensing module 400 is disposed on the inner step of the fixing part 120.

The pressurization header 200 is made of a transparent material such as light-transmitting quartz or glass, and is inserted and fixed into the insertion hole formed in the fixing part 120 of the attachment member 100. In particular, the pressurization header 200 having transparency may be formed in a hexahedral shape, a cube shape, a cylindrical shape, a column shape, or the like, corresponding to a shape and a size of the insertion hole formed in the fixing part 120 of the attachment member 100.

The pressurization header 200 may move in the pressurization direction, which is the downward direction, or in the detachment direction, which is the upward direction, in the same manner as the attachment member 100 in a state in which it is inserted into the fixing part 120 of the attachment member 100. As an example, the pressurization header 200 made of the transparent material may move in the pressurization direction in the same manner as the attachment member 100 to pressurize a transfer layer, a wafer, or the like, disposed in the pressurization direction. The pressurization header 200 made of the transparent material may transmit and emit laser light applied from the upward direction, which is a rear surface direction, to the downward direction, which is the pressurization direction, therethrough.

The fixing frame 130 may be formed to be attached or assembled to an outer side surface of the attachment member 100 or may be formed integrally with the attachment member 100. The fixing frame 130 is formed to protrude from the outer side surface of the attachment member 100. The fixing frame 130 may be around (e.g., may surround) the outer side surface of the attachment member 100 and protrude in a quadrangular shape, a hemispherical shape, or the like. A rear surface or an outer side surface of the fixing frame 130 is coupled to the attachment driving member 300. The fixing frame 130, the pressurization header 200, and the attachment member 100 are moved in the pressurization direction, which is the downward direction, or the detachment direction, which is the upward direction, by the driving of the attachment driving member 300.

The attachment driving member 300 includes a flat plate support frame and a plurality of pneumatic or hydraulic pressure regulators coupled to the flat plate support frame. The attachment driving member 300 moves the fixing frame 130, the pressurization header 200, and the attachment member 100 using the plurality of pressure regulators. The plurality of pressure regulators are disposed in a downward direction of the flat plate support frame. Lengths of the plurality of pressure regulators are adjusted according to changes in the amount of internal air pressure or hydraulic pressure. The attachment driving member 300 may move the fixing frame 130, the pressurization header 200, and the attachment member 100 in the pressurization direction, which is the downward direction, or move the upward direction, which is an opposite direction to the pressurization direction, by changing the length of each of the pressure regulators.

The first pressure sensing module 400 is disposed on a step surface formed inside the attachment member 100. The first pressure sensing module 400 may be formed in a quadrangular ring or O-ring shape corresponding to a shape and an area of the inner step of the fixing part 120. The first pressure sensing module 400 may be separately disposed in the form of a plurality of pieces on the step surface inside the attachment member 100.

The first pressure sensing module 400 includes a plurality of pressure sensors and at least one signal transmission circuit. The first pressure sensing module 400 senses a magnitude of pressure applied to the pressurization header 200 with the plurality of pressure sensors, and generates first pressure detection signals based on the magnitude of pressure applied to the pressurization header 200. The first pressure sensing module 400 may transmit the first pressure detection signals to the gradient setting module 500 using the signal transmission circuit.

The gradient setting module 500 detects a horizontal gradient of the pressurization header 200 by comparing and analyzing a pressurization force of the attachment driving member 300 and magnitudes of the first pressure detection signals of the first pressure sensing module 400 with each other. In addition, the gradient setting module 500 calculates horizontal gradient setting values for adjusting the horizontal gradient of the pressurization header 200. For example, the sum of pressures of the pressurization header 200 according to the first pressure detection signals may be the same as the pressurization force of the attachment driving member 300. Accordingly, the gradient setting module 500 may detect a magnitude deviation between the first pressure detection signals detected through the first pressure sensing module 400, and may calculate the horizontal gradient setting values of the pressurization header 200 for making the magnitude deviation between the first pressure detection signals zero. That is, the gradient setting module 500 may calculate the horizontal gradient setting values for adjusting the horizontal gradient of the pressurization header 200 so that the magnitude deviation between the first pressure detection signals becomes zero.

The gradient control module 510 adjusts a horizontal gradient of the flat plate support frame of the attachment driving member 300 according to the horizontal gradient setting values set by the gradient setting module 500. As the horizontal gradient of the flat plate support frame is adjusted, horizontal gradients of the plurality of pressure regulators, the attachment member 100, and the pressurization header 200 disposed on the flat plate support frame are adjusted.

The gradient control module 510 includes a plurality of linear motion (LM) guides disposed on a rear surface portion of the flat plate support frame and each disposed at positions each corresponding to the plurality of pressure regulators. In addition, the gradient control module 510 may include a plurality of magnet springs supporting the respective LM guides and at least one servo motor adjusting horizontal gradients of the flat plate support frame and the plurality of pressure regulators by changing a disposition position of each of the plurality of LM guides.

In one or more embodiments, an opening hole 330 corresponding to the opening 110 of the attachment member 100 is formed in the gradient control module 510 and the flat plate support frame of the attachment driving member 300. A shape and an area of the opening hole 330 formed in the gradient control module 510 and the attachment driving member 300 may correspond to and may be the same as those of the opening 110 of the attachment member 100.

The second pressure sensing module 800 is disposed in a pressurization holder of a pressurization plate 810, and generates second pressure detection signals according to a magnitude of pressure applied from the pressurization header 200. The second pressure sensing module 800 may be formed in a flat plate shape corresponding to a shape and an area of the pressurization holder of the pressurization plate 810 or may be separately disposed inside the pressurization holder in the form of pieces. A compression plate 830 for pressure distribution may be further disposed on a front surface or an upper surface of the second pressure sensing module 800.

The second pressure sensing module 800 includes a plurality of pressure sensors and at least one signal transmission circuit. Accordingly, the second pressure sensing module 800 generates the second pressure detection signals according to the magnitude of the pressure applied from the pressurization header 200 using the plurality of pressure sensors. In addition, the second pressure sensing module 800 may transmit the second pressure detection signals to the gradient setting module 500 through at least one signal transmission circuit.

The gradient setting module 500 receives the second pressure detection signals transmitted through the signal transmission circuit of the second pressure sensing module 800. The gradient setting module 500 may detect the horizontal gradient of the pressurization header 200 by comparing and analyzing magnitudes of pressure according to the second pressure detection signals with each other. In addition, the gradient setting module 500 may calculate horizontal gradient setting values for adjusting the horizontal gradient of the pressurization header 200. For example, the gradient setting module 500 may detect each pressure magnitude deviation according to the second pressure detection signals, and calculate the horizontal gradient setting values for adjusting the horizontal gradient of the pressurization header 200 so that the pressure magnitude deviation according to the second pressure detection signals becomes zero. The gradient setting module 500 generates gradient control signals corresponding to magnitudes of the calculated horizontal gradient setting values and transmits the gradient control signals to the gradient control module 510.

The gradient control module 510 adjusts the horizontal gradient of the flat plate support frame of the attachment driving member 300 based on the horizontal gradient set values set by the gradient setting module 500 and the gradient control signals generated by the gradient setting module 500. As the horizontal gradient of the flat plate support frame is adjusted, horizontal gradients of the plurality of pressure regulators, the attachment member 100, and the pressurization header 200 formed on the flat plate support frame are adjusted.

The laser irradiation member 700 is disposed in a rear surface direction of the attachment member 100, for example, in an upward direction of the attachment member 100, and irradiates laser light in a direction of the opening hole 330 of the gradient control module 510 and the attachment driving member 300 and the opening 110 of the attachment member 100. The laser light penetrating through the opening hole 330 of the gradient control module 510 and the attachment driving member 300 and the opening 110 of the attachment member 100 is emitted in a front surface direction of the pressurization header 200 through the pressurization header 200.

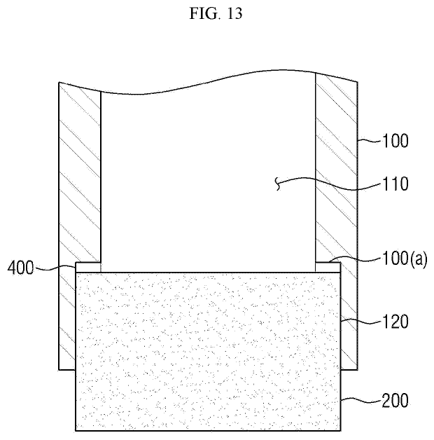

FIG. 13 is a cross-sectional view illustrating cross-sectional structures of an attachment member and a fixing part of the attachment member illustrated in FIG. 12.

Referring to FIG. 13, an inner diameter of the fixing part 120 of the attachment member 100 into which the pressurization header 200 is inserted, that is, the insertion hole formed inside the fixing part 120, is greater than an inner diameter of the opening 110 penetrating through the inside of the attachment member 100. Accordingly, a step 100(a) according to a difference in inner diameter between the opening 110 of the attachment member 100 and the insertion hole of the pressurization header 200 is formed inside the fixing part 120. A quadrangular ring-type or O-ring-type first pressure sensing module 400 is disposed on the inner step 100(a) of the insertion hole. As described above, the first pressure sensing module 400 may be separated into a plurality of pieces, and the plurality of pieces of the first pressure sensing module 400 may be separately disposed on an inner step 100(a) surface of the insertion hole.

In a state in which the first pressure sensing module 400 is disposed on the inner step 100(a) surface of the insertion hole, the pressurization header 200 is inserted and fixed into the insertion hole so as to be in contact with the first pressure sensing module 400. The pressurization header 200 may pressurize the pressurization holder of the pressurization plate 810 and the compression plate 830 by moving in the pressurization direction, which is downward direction, in the same manner as the attachment member 100 in a state in which it is inserted into the insertion hole of the fixing part 120.

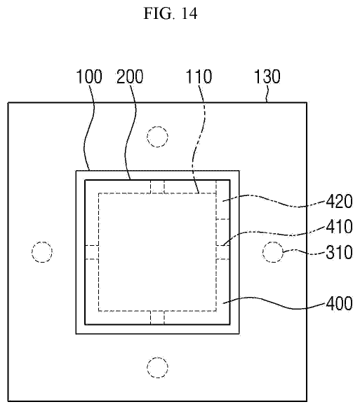

FIG. 14 is a configuration view illustrating lower surfaces of a pressurization header, the attachment member, and a fixing frame of FIGS. 12 and 13 in an upward direction.

Referring to FIG. 14, pressure regulators 310 of the attachment driving member 300 may be coupled to the fixing frame 130 in a rear surface direction of the fixing frame 130, and the fixing frame 130, the pressurization header 200, and the attachment member 100 may be moved in upward and downward directions by the pressure regulators 310.

The pressure regulators 310 of the attachment driving member 300 may be coupled to the 2-axis, 3-axis, or 4-axis directions of the fixing frame 130, respectively. For example, four pressure regulators 310 may be coupled to x-axis, −x-axis, y-axis, and −y-axis directions of side surfaces or a rear surface of the fixing frame 130, respectively. Lengths of the four pressure regulators 310 may be adjusted in the upward and downward directions (or forward and backward directions), and the fixing frame 130, the pressurization header 200, and the attachment member 100 may be moved in the upward and downward directions (or forward and backward directions) according to a change in the lengths of the pressure regulators 310.

Because the inner diameter of the insertion hole into which the pressurization header 200 is fixed is greater than the inner diameter of the opening 110 penetrating through the inside of the attachment member 100, the quadrangular ring-type first pressure sensing module 400 may be disposed on the inner step 100(a) of the insertion hole.

Referring to FIG. 14, the quadrangular ring-type first pressure sensing module 400 includes a plurality of pressure sensors 410 and at least one signal transmission circuit 420.

The plurality of pressure sensors 410 are disposed at positions in different directions, respectively, detect the pressure applied from the pressurization header 200, and generate first pressure detection signals according to magnitudes of the detected pressure.

At least one signal transmission circuit 420 transmits the first pressure detection signals generated by the plurality of pressure sensors 410 to the gradient setting module 500.

The plurality of pressure sensors 410 may be disposed, respectively, in 4-axis directions of the insertion hole into which the pressurization header 200 is fixed. For example, the plurality of pressure sensors 410 may be disposed, respectively, in x-axis, −x-axis, y-axis, and −y-axis directions corresponding to coupled positions of the pressure regulators 310 coupled to the fixing frame 130. The number and disposition positions of pressure sensors 410 are not limited to those illustrated in FIG. 14, and the plurality of pressure sensors 410 may be provided in two or more numbers and may be disposed in two or more axis directions and may be disposed in axis directions of a polygon such as a straight line, a triangle, a quadrangle, a pentagon, or a hexagon. Alternatively, the plurality of pressure sensors 410 may be disposed in a polygonal shape such as a triangular shape, a quadrangular shape, a pentagonal shape, or a hexagonal shape.

At least one signal transmission circuit 420 receives the first pressure detection signals from the plurality of pressure sensors 410 in real time, and transmits the first pressure detection signals according to the magnitudes of the pressure together with directional codes for the respective pressure sensors 410 to the gradient setting module 500. To this end, at least one signal transmission circuit 420 may further include a short-distance interface communication circuit transmitting the first pressure detection signals in a wired or wireless manner.

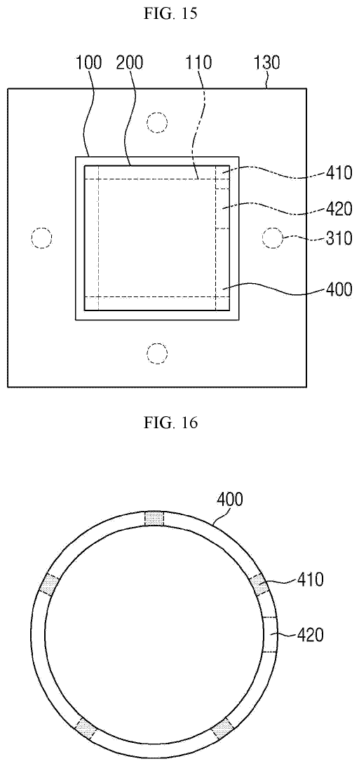

FIG. 15 is a configuration view of one or more embodiments illustrating lower surfaces of a pressurization header, the attachment member, and the fixing frame of FIGS. 12 and 13 in an upward direction.

Referring to FIG. 15, the plurality of pressure sensors 410 may be disposed, respectively, at corner positions of the inner step 100(a) according to shapes of the insertion hole into which the pressurization header 200 is fixed and the inner step 100(a). For example, the plurality of pressure sensors 410 may be disposed, respectively, at four-direction corner positions of the inner step 100(a) formed in a quadrangular shape. The number and disposition positions of pressure sensors 410 are not limited to those illustrated in FIG. 15, and the plurality of pressure sensors 410 may be provided in two or more numbers and may be disposed in a polygonal shape such as a triangular shape, a quadrangular shape, a pentagonal shape, or a hexagonal shape.

At least one signal transmission circuit 420 is disposed at a position adjacent to any one pressure sensor 410 and receives the first pressure detection signals from the respective pressure sensors 410. In addition, at least one signal transmission circuit 420 transmits the first pressure detection signals according to the magnitudes of the pressure together with directional codes for the respective pressure sensors 410 to the gradient setting module 500.

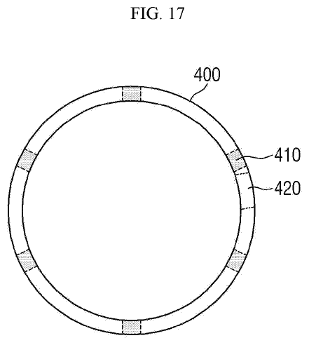

FIG. 16 is a configuration view of another embodiment illustrating a disposition shape of a first pressure sensing module illustrated in FIGS. 14 and 15. In addition, FIG. 17 is a configuration view of still another embodiment illustrating a disposition shape of a first pressure sensing module illustrated in FIGS. 14 and 15.

As illustrated in FIGS. 16 and 17, the first pressure sensing module 400 may be formed in an O-ring shape so as to correspond to a shape and an area of the inner step of the fixing part 120. A plurality of pressure sensors 410 included in the O-ring-type first pressure sensing module 400 may be disposed, respectively, in axis directions of a polygon such as a pentagon in addition to a triangle or a quadrangle.

As an example, the pressure regulators 310 of the attachment driving member 300 may be disposed and coupled, respectively, in axis directions of a polygon such as a pentagon and a hexagon in addition to a triangle and a quadrangle, in a rear surface direction of the fixing frame 130. Accordingly, the plurality of pressure sensors 410 may be disposed, respectively, in axis directions of a polygon such as a pentagon or a hexagon so as to correspond, respectively, to axis directions of a polygon of the insertion hole into which the pressurization header 200 is fixed.

At least one signal transmission circuit 420 disposed adjacent to at least one pressure sensor 410 transmits the first pressure detection signals from the plurality of pressure sensors 410 together with directional codes for the respective pressure sensors 410 to the gradient setting module 500.

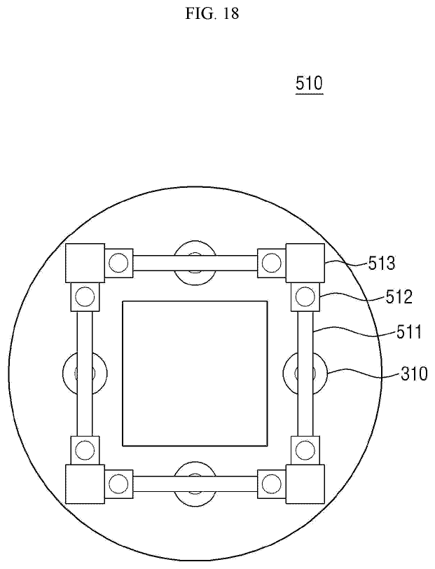

FIG. 18 is a configuration view illustrating a structure, in a plan view, of a gradient control module illustrated in FIGS. 11 and 12.

Referring to FIG. 18, the gradient control module 510 includes a plurality of LM guides 511, a plurality of magnet springs 512, and at least one servo motor 513.

The plurality of LM guides 511 are arranged to support the pressure regulators 310 and the flat plate support frame in a rear surface direction of the pressure regulators 310. Specifically, the respective LM guides 511 may be disposed on the flat plate support frame at positions corresponding to disposition positions of the pressure regulators 310, and may support the pressure regulators 310 in the rear surface direction. When the respective LM guides 511 pressurize the pressure regulators 310 in the rear surface direction, the pressure regulators 310 may be pressurized in the downward direction. On the other hand, when a pressurization force for the pressure regulators 310 is lowered, the pressure regulators 310 may be moved in the upward direction.

The plurality of magnet springs 512 are disposed between the LM guides 511 and support at least one side surfaces of the LM guides 511. The respective magnet springs 512 may be rotatably disposed in a helical screw structure to change heights or positions, in the upward and downward directions, of the LM guides 511 supported on side surfaces thereof according to a rotation direction. That is, when each magnet spring 512 rotates in a first horizontal direction (or clockwise direction), at least one LM guide 511 in contact with a side surface of each magnet spring 512 may be moved in the downward direction, which is a disposition direction of the pressure regulator 310. On the other hand, when each magnet spring 512 rotates in a second horizontal direction (or counterclockwise direction), at least one LM guide 511 in contact with a side surface of each magnet spring 512 may be moved in the upward direction in which it becomes distant from the pressure regulator 310.

At least one servo motor 513 rotates at least one of the plurality of magnet springs 512 in the first horizontal direction (or clockwise direction) or the second horizontal direction (or counterclockwise direction) in response to the horizontal gradient setting values set by the gradient setting module 500 and the gradient control signals generated by the gradient setting module 500. At least one rotation direction or rotation axis transformation gears may be formed in at least one servo motor 513. At least one servo motor 513 adjusts an amount of rotation of at least one magnet spring 512 based on a magnitude of the gradient control signal. A height of each of the pressure regulators 310 may be adjusted according to a degree of rotation of at least one magnet spring 512 rotating in the first or second horizontal direction.

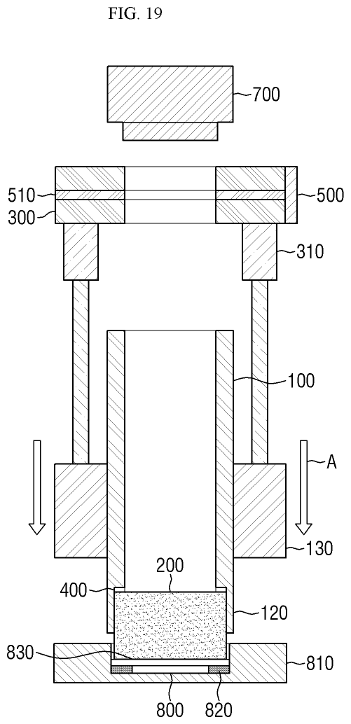

FIG. 19 is a cross-sectional structural view for describing a pressurizing process of a second pressure sensing module through the pressurization header and a horizontal gradient correcting process of the pressurization header.

Referring to FIG. 19, in order to correct and adjust the horizontal gradient of the pressurization header 200, the attachment driving member 300 moves the fixing frame 130, the pressurization header 200, and the attachment member 100 using a plurality of pressure regulators 310. The fixing frame 130, the pressurization header 200, and the attachment member 100 may move in the downward direction (direction of arrow A), which is the pressurization direction, according to a change in lengths of the pressure regulators 310.

The pressurization header 200 may be moved in the downward direction (direction of arrow A) by the pressure regulators 310 to be inserted into the pressurization holder of the pressurization plate 810. In addition, the pressurization header 200 may pressurize the compression plate 830 and the second pressure sensing module 800 disposed inside the pressurization holder of the pressurization plate 810.

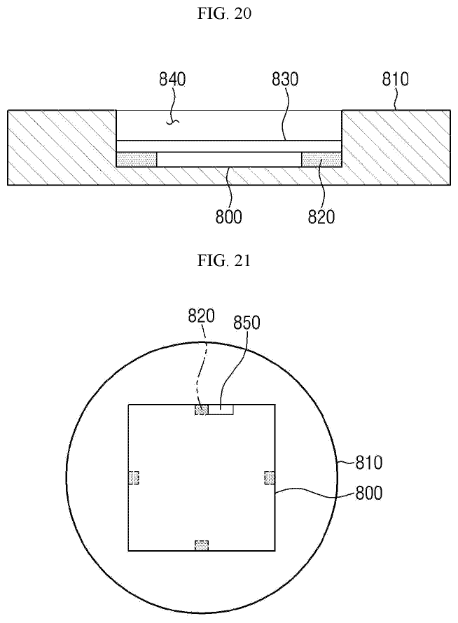

FIG. 20 is a cross-sectional view illustrating, in detail, cross-sectional structures of a pressurization plate and the second pressure sensing module illustrated in FIG. 19. In addition, FIG. 21 is a front view illustrating a disposition structure of the pressurization plate and the second pressure sensing module illustrated in FIGS. 19 and 20.

Referring first to FIG. 20 together with FIG. 19, the pressurization header 200 may be inserted into the pressurization holder 840 of the pressurization plate 810 by the pressure regulators 310 to pressurize the compression plate 830 and the second pressure sensing module 800 disposed inside the pressurization holder 840.

The second pressure sensing module 800 generates the second pressure detection signals according to the magnitude of the pressure applied from the pressurization header 200 using a plurality of pressure sensors 820. In addition, the second pressure sensing module 800 may transmit the second pressure detection signals to the gradient setting module 500 through at least one signal transmission circuit 850.

Referring to FIG. 21, the second pressure sensing module 800 includes the plurality of pressure sensors 820 and at least one signal transmission circuit 850.

The plurality of pressure sensors 820 may be disposed in two or more axis directions of the pressurization holder 840 into which the pressurization header 200 is inserted or may be disposed, respectively, in 4-axis directions of the pressurization holder 840. For example, the plurality of pressure sensors 820 may be disposed, respectively, in x-axis, −x-axis, y-axis, and −y-axis directions on an inner plane of the pressurization holder 840.

The plurality of pressure sensors 820 detect the pressure applied from the pressurization header 200, and generate the second pressure detection signals according to magnitudes of the detected pressure.

At least one signal transmission circuit 850 may be disposed at a position adjacent to at least one of the plurality of pressure sensors 820. At least one signal transmission circuit 850 transmits the second pressure detection signals generated by the plurality of pressure sensors 820 to the gradient setting module 500.

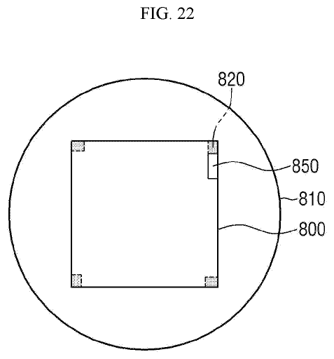

FIG. 22 is a front view of one or more embodiments illustrating a disposition structure of the pressurization plate and the second pressure sensing module illustrated in FIGS. 19 and 20.

The plurality of pressure sensors 820 may be disposed, respectively, at inner corner positions of the pressurization holder 840 according to a shape of the inner plane of the pressurization holder 840 into which the pressurization header 200 is inserted. For example, the plurality of pressure sensors 820 may be disposed, respectively, at four direction corner positions of the pressurization holder 840 formed in a quadrangular plane shape. The number and disposition positions of pressure sensors 820 are not limited to those illustrated in FIG. 22, and the plurality of pressure sensors 820 may be provided in two or more numbers and may be disposed in two or more axis directions or may be disposed, respectively, at corner positions of a polygon such as a triangle, a quadrangle, a pentagon, or a hexagon. The plurality of pressure sensors 820 may be disposed in a polygonal shape such as a triangular shape, a quadrangular shape, a pentagonal shape, or a hexagonal shape.

At least one signal transmission circuit 850 is disposed at a position adjacent to any one pressure sensor 820 and receives the second pressure detection signals from the respective pressure sensors 820. In addition, at least one signal transmission circuit 850 transmits the second pressure detection signals according to the magnitudes of the pressure together with directional codes for the respective pressure sensors 820 to the gradient setting module 500.

When the second pressure detection signals are received through the signal transmission circuit 850 of the second pressure sensing module 800, the gradient setting module 500 may detect the horizontal gradient of the pressurization header 200 by comparing and analyzing the magnitudes of the pressure according to the second pressure detection signals with each other. In addition, the gradient setting module 500 may calculate the horizontal gradient setting values for adjusting the horizontal gradient of the pressurization header 200.

The gradient setting module 500 may detect each pressure magnitude deviation according to the second pressure detection signals, and calculate the horizontal gradient setting values for adjusting the horizontal gradient of the pressurization header 200 so that the pressure magnitude deviation according to the second pressure detection signals becomes zero. The gradient setting module 500 generates the gradient control signals corresponding to the magnitudes of the calculated horizontal gradient setting values and transmits the gradient control signals to the gradient control module 510.

The gradient control module 510 adjusts the horizontal gradient of the flat plate support frame of the attachment driving member 300 based on the horizontal gradient set values set by the gradient setting module 500 and the gradient control signals generated by the gradient setting module 500. As the horizontal gradient of the flat plate support frame is adjusted, horizontal gradients of the plurality of pressure regulators, the attachment member 100, and the pressurization header 200 formed on the flat plate support frame are adjusted.

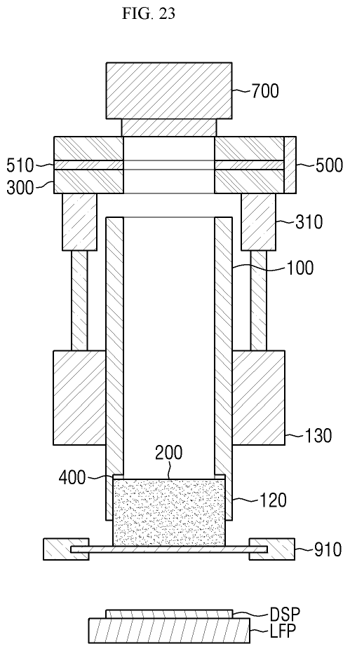

FIG. 23 is a cross-sectional structural view illustrating a fabricating process of a display panel using the apparatus for fabricating a display panel according to one or more embodiments.

As illustrated in FIG. 23, when the horizontal gradients of the flat plate support frame of the attachment driving member 300, the attachment member 100, and the pressurization header 200 are adjusted by the gradient control module 510, a plurality of light emitting elements LE may be attached onto a display substrate DSP using the apparatus for fabricating a display panel.

A wafer mounting member 910 may be disposed in the downward direction, which is the pressurization direction of the attachment member 100 and the pressurization header 200. A wafer having the plurality of light emitting elements LE formed thereon is fixed to the wafer mounting member 910, and the wafer mounting member 910 fixes the wafer so that the plurality of light emitting elements LE are disposed in the downward direction. The display substrate DSP constituting a display device is disposed on a substrate loading plate LFP in the downward direction facing the wafer mounting member 910.

The attachment member 100 and the pressurization header 200 are moved in the downward direction by the attachment driving member 300, such that the pressurization header 200 may be in contact with a rear surface of the wafer on which the plurality of light emitting elements LE are formed. The pressurization header 200 pressurizes the rear surface of the wafer to allow the plurality of light emitting elements LE formed on the wafer to be attached onto the display substrate DSP.

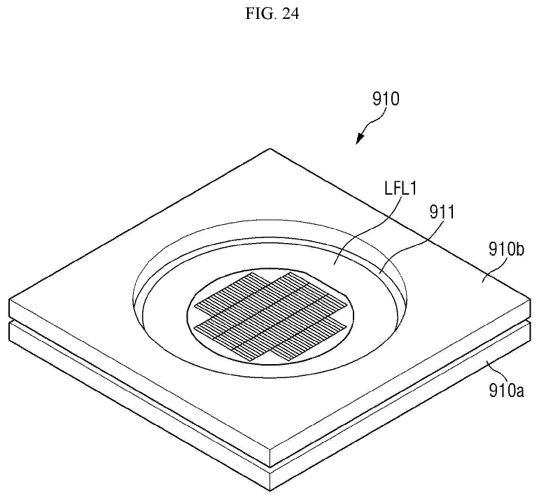

FIG. 24 is a perspective view illustrating, in detail, a wafer mounting member illustrated in FIG. 23.

Referring to FIG. 24, the wafer mounting member 910 includes a first mounting frame 910a on which a wafer LFL1 having a plurality of light emitting elements LE formed thereon is seated, and a second mounting frame 910b pressurizing a portion of a front surface and an outer periphery or circumference of the wafer LFL1 seated on the first mounting frame 910a to fix the wafer LFL1.

The first mounting frame 910a is formed in a shape of a polygonal panel or frame in which a quadrangular or circular opening is formed. In addition, the second mounting frame 910b may also be formed in a shape of a polygonal panel or frame in which a quadrangular or circular opening is formed, and may be assembled to the first mounting frame 910a in a shape in which it faces the first mounting frame 910a. That is, the first and second mounting frames 910a and 910b are assembled to each other so as to face and overlap each other, and may thus pressurize an outer peripheral or circumferential region 911 and portions of front and rear surfaces of the wafer LFL1 excluding an opening region to fix the wafer LFL1.

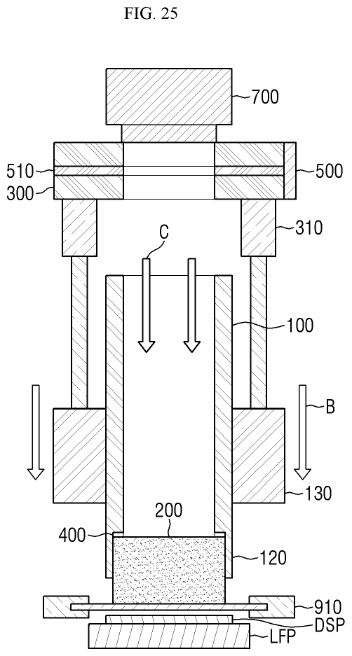

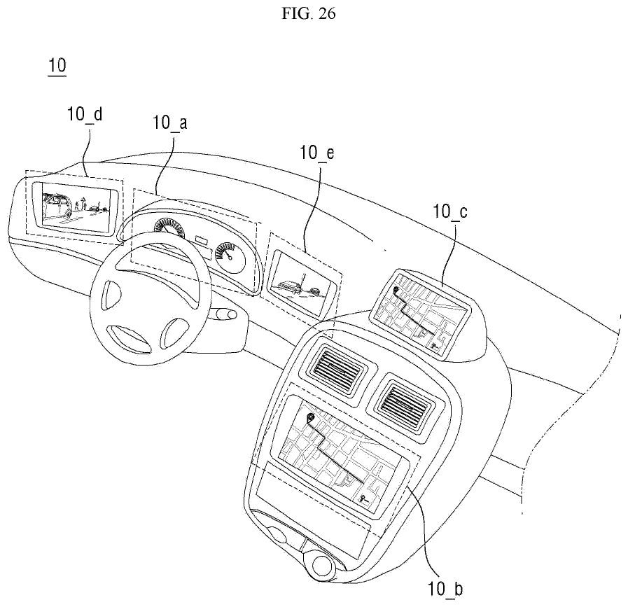

FIG. 25 is a cross-sectional structural view illustrating a wafer pressurizing process using the apparatus for fabricating a display panel according to one or more embodiments.

As illustrated in FIG. 25, the attachment member 100 and the pressurization header 200 are moved in the downward direction, that is, a direction of arrow B, by the attachment driving member 300 in a state in which the wafer mounting member 910 is disposed in the downward direction, which is the pressurization direction of the pressurization header 200. The pressurization header 200 may move in the direction of arrow B to be in contact with the rear surface of the wafer LFL1 on which the plurality of light emitting elements LE are formed.

In a state in which the rear surface of the wafer LFL1 is in contact with the pressurization header 200, the pressurization header 200 and the wafer LFL1 may be moved in the downward direction, which is the pressurization direction, that is, in a loading direction of the display substrate DSP.

The pressurization header 200 pressurizes the rear surface of the wafer LFL1 to allow the plurality of light emitting elements LE formed in a front surface direction of the wafer LFL1 to be attached onto the display substrate DSP.

The laser irradiation member 700 irradiates laser light in a direction of the opening hole 330 of the gradient control module 510 and the attachment driving member 300 and the opening 110 of the attachment member 100, that is, in a direction of arrow C. The laser light penetrating through the opening hole 330 of the gradient control module 510 and the attachment driving member 300 and the opening 110 of the attachment member 100 is emitted in a front surface direction of the pressurization header 200 through the pressurization header 200. The plurality of light emitting elements LE may be adhered to the display substrate DSP, and may be attached onto the display substrate DSP while being heated by the laser light.

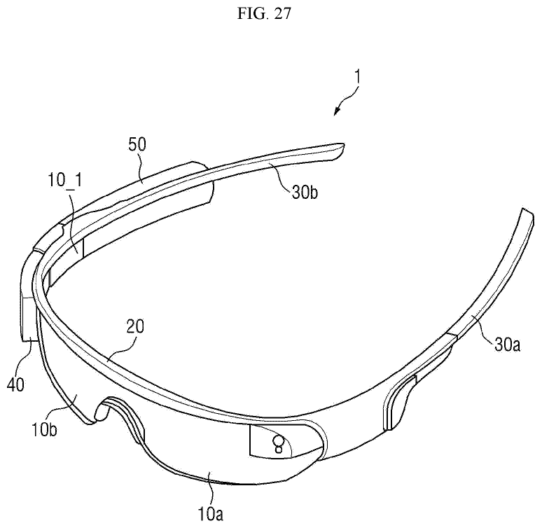

FIG. 26 is an illustrative view illustrating an instrument board and a center fascia of a vehicle including the display device according to one or more embodiments.

Referring to FIG. 26, display panels or micro display substrates 101 included in the display device according to the present disclosure may be applied to display apparatuses or display devices 10 of a dashboard of a vehicle. As an example, the display devices 10 to which light emitting elements LE such as micro LEDs are applied may be applied to an instrument board 10_a of the vehicle, may be applied to a center fascia 10_b of the vehicle, or may be applied to a center information display (CID) 10_c disposed on the dashboard of the vehicle. In addition, the display devices 10 according to one or more embodiments may be applied to room mirror displays 10_d and 10_e substituting for side mirrors of the vehicle, a navigation device, and the like.

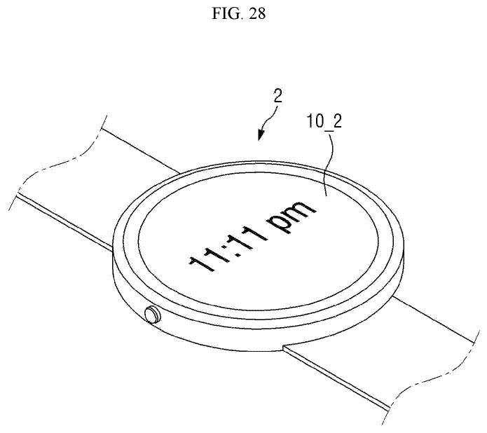

FIG. 27 is an illustrative view illustrating a glasses-type virtual reality device including the display device according to one or more embodiments. In addition, FIG. 28 is an illustrative view illustrating a watch-type smart device including the display device according to one or more embodiments.

FIG. 27 illustrates an eyeglasses-type virtual reality device 1 including eyeglasses frame legs 30a and 30b. The eyeglasses-type virtual reality device 1 according to one or more embodiments may include a virtual image display device 10-1, a left eye lens 10a, a right eye lens 10b, a support frame 20, eyeglasses frame legs 30a and 30b, a reflective member 40, and a display device accommodating part 50. The virtual image display device 10_1 may display a virtual image using the micro display substrates 101 illustrated as an embodiment of the present disclosure.

The eyeglasses-type virtual reality device 1 according to one or more embodiments may also be applied to a head mounted display including a head mounted band that may be mounted on a user's head instead of the eyeglasses frame legs 30a and 30b. That is, the eyeglasses-type virtual reality device 1 according to one or more embodiments are not limited to that illustrated in FIG. 27, and may be applied in various forms to various other electronic devices.

In addition, as illustrated in FIG. 28, the micro display substrates 101 illustrated as an embodiment of the present disclosure may be applied to a position display device 10_2 of a watch-type smart device 2, which is one of smart devices.

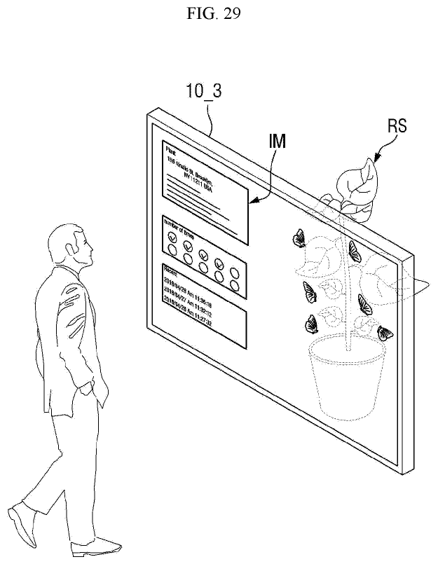

FIG. 29 is an illustrative view illustrating a transparent display device including the display device according to one or more embodiments.

Referring to FIG. 29, the micro display substrates 101 illustrated as an embodiment of the present disclosure may be applied to a transparent display device. The transparent display device may transmit light therethrough while displaying an image IM. Therefore, a user positioned on a front surface of the transparent display device may not only view the image IM displayed on the micro display panel, but also see an object RS or a background positioned on a rear surface of the transparent display device. When the micro display substrate 101 is applied to the transparent display device, the micro display substrate 101 illustrated in FIG. 29 may include a light transmitting part capable of transmitting light or may be made of a material capable of transmitting light.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. An apparatus for fabricating a display panel, comprising:
an attachment member having a fixing portion in a pressurization direction to which a pressurization header is fixed;
an attachment driving member configured to move the attachment member and the pressurization header in the pressurization direction or a detachment direction through a fixing frame of the attachment member;
a first pressure sensing module between the pressurization header and the attachment member and configured to generate first pressure detection signals according to pressure applied to the pressurization header;
a gradient setting module configured to set a gradient of the pressurization header based on magnitudes of the first pressure detection signals; and
a gradient control module configured to adjust gradients of the pressurization header, the attachment member, and the fixing frame according to control of the gradient setting module.

2. The apparatus for fabricating a display panel of claim 1, wherein the attachment member has a polyprismatic shape or a cylindrical shape and has a polygonal shape or a circular shape opening, wherein an insertion hole into which the pressurization header is inserted and fixed is located in a fixing part of the attachment member in the pressurization direction, and wherein the insertion hole has a polygonal or cylindrical shape according to a shape of an outer peripheral surface of the pressurization header.

3. The apparatus for fabricating a display panel of claim 2, wherein an inner step is located in the fixing part according to a difference in inner diameter between the opening of the attachment member and the insertion hole, and the first pressure sensing module is on the inner step of the fixing part.

4. The apparatus for fabricating a display panel of claim 3, wherein the first pressure sensing module has a quadrangular ring or O-ring shape corresponding to a shape and an area of the inner step of the fixing part or is separated into a plurality of pieces, and the plurality of pieces of the first pressure sensing module are separately located on the inner step of the fixing part, and the pressurization header is inserted into the insertion hole of the fixing part and contacting the first pressure sensing module.

5. The apparatus for fabricating a display panel of claim 3, wherein the pressurization header comprises a transparent material including at least one of light-transmitting quartz or glass, and has a hexahedral shape, a cube shape, a cylindrical shape, or a column shape corresponding to a shape and a size of the insertion hole in the fixing part of the attachment member.

6. The apparatus for fabricating a display panel of claim 3, wherein the first pressure sensing module is configured to: sense a magnitude of the pressure applied to the pressurization header using a plurality of pressure sensors located, respectively, at positions in different directions and generate the first pressure detection signals based on the magnitude of the pressure; and
transmit the first pressure detection signals together with a directional code for each of the plurality of pressure sensors to the gradient setting module using at least one signal transmission circuit.

7. The apparatus for fabricating a display panel of claim 6, wherein the plurality of pressure sensors are:
located, respectively, in x-axis, −x-axis, y-axis, and −y-axis directions on the inner step of the fixing part;
located, respectively, at four-direction corner positions of the inner step formed in a quadrangular shape; or
located on the inner step and have one polygonal shape selected from the group of a triangular shape, a quadrangular shape, a pentagonal shape, or a hexagonal shape and located on the inner step.

8. The apparatus for fabricating a display panel of claim 6, wherein the gradient setting module is configured to:
detect a magnitude deviation between the first pressure detection signals and calculate horizontal gradient setting values of the pressurization header to make the magnitude deviation between the first pressure detection signals zero; and
generate gradient control signals corresponding to magnitudes of the calculated horizontal gradient setting values and transmit the gradient control signals to the gradient control module.

9. The apparatus for fabricating a display panel of claim 8, wherein the attachment driving member is configured to move the fixing frame, the attachment member, and the pressurization header in the pressurization direction or the detachment direction opposite to the pressurization direction using a plurality of pressure regulators located in a downward direction of a flat plate support frame.

10. The apparatus for fabricating a display panel of claim 9, wherein the gradient control module comprises:
a plurality of linear motion (LM) guides, the plurality of LM guides located at positions corresponding to the plurality of pressure regulators on a rear surface portion of the flat plate support frame;
a plurality of magnet springs supporting the plurality of LM guides, respectively; and
at least one servo motor configured to adjust horizontal gradients of the flat plate support frame and the plurality of pressure regulators by changing a disposition position of each of the plurality of magnet springs and the plurality of LM guides according to the gradient control signals from the gradient setting module.

11. The apparatus for fabricating a display panel of claim 10, wherein the gradient control module is configured to adjust horizontal gradients of the plurality of pressure regulators, the attachment member, and the pressurization header located on the flat plate support frame by adjusting the horizontal gradient of the flat plate support frame of the attachment driving member based on the gradient control signals.

12. The apparatus for fabricating a display panel of claim 2, further comprising a second pressure sensing module located in a pressurization holder of a pressurization plate pressurized by the pressurization header and generating second pressure detection signals according to a magnitude of pressure applied from the pressurization header,
wherein the second pressure sensing module is in a flat plate shape corresponding to a shape and an area of the pressurization holder or is separately located inside the pressurization holder in the form of pieces.

13. The apparatus for fabricating a display panel of claim 12, wherein the second pressure sensing module is configured to:
generate the second pressure detection signals according to the magnitude of the pressure applied from the pressurization header using a plurality of pressure sensors located at positions in different directions; and
transmit the second pressure detection signals together with a directional code for each of the plurality of pressure sensors to the gradient setting module through at least one signal transmission circuit.

14. The apparatus for fabricating a display panel of claim 13, wherein the gradient setting module configured to detect a magnitude deviation between the second pressure detection signals and to calculate horizontal gradient setting values of the pressurization header to make the magnitude deviation between the second pressure detection signals zero.

15. The apparatus for fabricating a display panel of claim 13, wherein the plurality of pressure sensors:
are located, respectively, in x-axis, −x-axis, y-axis, and −y-axis directions inside the pressurization holder of the pressurization plate;
are located, respectively, at four-direction corner positions inside the pressurization holder formed in a quadrangular shape; or
has one polygonal shape of a triangular shape, a quadrangular shape, a pentagonal shape, or a hexagonal shape inside the pressurization holder.

16. The apparatus for fabricating a display panel of claim 13, wherein the gradient setting module is configured to detect pressure magnitude deviations according to the second pressure detection signals, to calculate horizontal gradient setting values to adjust a horizontal gradient of the pressurization header to make the pressure magnitude deviation according to the second pressure detection signals zero, to generate gradient control signals corresponding to magnitudes of the calculated horizontal gradient setting values, and to transmit the gradient control signals to the gradient control module.

17. The apparatus for fabricating a display panel of claim 16, wherein the gradient control module is configured to adjust horizontal gradients of the plurality of pressure regulators, the attachment member, and the pressurization header located on the flat plate support frame by adjusting a horizontal gradient of a flat plate support frame of the attachment driving member based on the gradient control signals.

18. A fabricating method of a display panel, comprising:
fixing a pressurization header to a fixing part, in a pressurization direction, of an attachment member;
moving a fixing frame of the attachment member, the attachment member, and the pressurization header in the pressurization direction using an attachment driving member;
generating first pressure detection signals according to pressure applied to the pressurization header using a first pressure sensing module; and
setting a gradient of the pressurization header based on magnitudes of the first pressure detection signals and adjusting gradients of the pressurization header, the attachment member, and the fixing frame.

19. The fabricating method of a display panel of claim 18, wherein the generating of the first pressure detection signals comprises:
sensing a magnitude of the pressure applied to the pressurization header using a plurality of pressure sensors located, respectively, between the pressurization header and the fixing part and generating the first pressure detection signals based on the magnitude of the pressure; and
transmitting the first pressure detection signals together with a directional code for each of the plurality of pressure sensors to a gradient setting module using at least one signal transmission circuit.

20. The fabricating method of a display panel of claim 19, wherein the adjusting of the gradients of the pressurization header, the attachment member, and the fixing frame comprises:
detecting a magnitude deviation between the first pressure detection signals and calculating horizontal gradient setting values of the pressurization header for making the magnitude deviation between the first pressure detection signals zero; and
generating gradient control signals corresponding to magnitudes of the calculated horizontal gradient setting values and adjusting the gradients of the pressurization header, the attachment member, and the fixing frame according to the gradient control signals.
